(19) United States
(12) Patent Application Publication
(10) Pub. No.: US 2026/0334047 A1
(43) Pub. Date: Oct. 22, 2026

(54) LIGHT EMITTING DEVICE, ELECTRONIC DEVICE INCLUDING THE SAME, AND MANUFACTURING METHOD OF THE SAME

(71) Applicant: Samsung Display Co., Ltd., Yongin-si (KR)

(72) Inventors: EON SEOK OH, Yongin-si (KR); HYUNGSIK KIM, Yongin-si (KR); JUNGJOON SEO, Yongin-si (KR); TAEHYUN SUNG, Yongin-si (KR); JE-HYUN SONG, Yongin-si (KR); YOUNGBIN CHOI, Yongin-si (KR)

(21) Appl. No.: 19/459,465

(22) Filed: Jan. 26, 2026

(30) Foreign Application Priority Data
Apr. 11, 2025 (KR) 10-2025-0047508

(51) Int. Cl. H10K 59/80; H10K 50/19; H10K 59/12; H10K 59/35; H10K 71/60; H10K 102/20

(52) U.S. Cl. CPC H10K 59/8052; H10K 50/19; H10K 59/1201; H10K 59/352; H10K 59/879; H10K 71/60; H10K 2102/20

(57) ABSTRACT

A light-emitting device may present disclosure include a first electrode, a second electrode above the first electrode and including a silver (Ag)-palladium (Pd)-copper (Cu) alloy, light-emitting stacks between the first electrode and the second electrode, respective light-emitting stacks including an emission layer, and a charge generation layer between the light-emitting stacks, where the second electrode may include, based on 100 wt % of a total weight of the Ag—Pd—Cu alloy, about 97.9 wt % or more and about 99.9 wt % or less of Ag, about 0.01 wt % or more and less than about 0.1 wt % of Pd, and about 0.01 wt % or more and about 2.0 wt % or less of Cu.

### CROSS-REFERENCE TO RELATED APPLICATIONS

The present application claims priority to and the benefit of Korean Patent Application No. 10-2025-0047508, filed on Apr. 11, 2025, in the Korean Intellectual Property Office, the entire disclosure of which is incorporated herein by reference.

### BACKGROUND

### 1. Field

Embodiments of the present disclosure herein relate to a light-emitting device, an electronic device including the light-emitting device, and a manufacturing method of the light-emitting device.

### 2. Description of the Related Art

Organic light-emitting devices are self-luminous devices that may have a fast response speed and be driven by a low voltage. Accordingly, the organic light-emitting display devices including organic light-emitting devices may be lightweight and thin by not including a separate light source. Furthermore, the organic light-emitting display devices may have advantages such as excellent luminance and no dependence on viewing angle.

An organic light-emitting device may be a display device having an emission layer including an organic material between an anode electrode and a cathode electrode. Holes provided from the anode electrode and electrons provided from the cathode electrode may be combined in the emission layer to form excitons, and then light corresponding to the energy between the holes and the electrons may be generated from the excitons.

A tandem organic light-emitting device may have a structure, in which two or more stacks of a hole transport layer/emission layer/electron transport layer may be provided between an anode electrode and a cathode electrode, and a charge generation layer exists between the two or more stacks to help the generation and movement of charges.

### SUMMARY

An aspect of the present disclosure may be to provide a light-emitting device having excellent emission efficiency and reduced sheet resistance of a common electrode.

Another aspect of the present disclosure may be to provide an electronic device having excellent display efficiency and improved power consumption.

A light-emitting device according to one or more embodiments of the present disclosure may include a first electrode, a second electrode above (e.g., on; disposed on; located on; or arranged on) the first electrode and including a silver (Ag)-palladium (Pd)-copper (Cu) alloy, light-emitting stacks between (e.g., disposed between) the first electrode and the second electrode, respective light-emitting stacks (e.g., each of the light-emitting stacks) including an emission layer, and a charge generation layer between the light-emitting stacks, where the second electrode may include, based on 100 wt % of a total weight of the Ag—Pd—Cu alloy (e.g., the total alloy), about 97.9 wt % or more and about 99.9 wt % or less of Ag, about 0.01 wt % or more and less than about 0.1 wt % of Pd, and about 0.01 wt % or more and about 2.0 wt % or less of Cu.

In one or more embodiments, the Ag—Pd—Cu alloy may further include nickel (Ni).

In one or more embodiments, the Ag—Pd—Cu alloy may further include, based on 100 wt % of the total weight of the Ag—Pd—Cu alloy, about 0.01 wt % or more and about 2.0 wt % or less of Ni.

In one or more embodiments, the second electrode may include (e.g., be composed of) the Ag—Pd—Cu alloy.

In one or more embodiments, a content of Pd in the second electrode may be less than a content of Cu of the second electrode.

In one or more embodiments, the light-emitting stacks may include a first light-emitting stack including a first emission layer, and a second light-emitting stack including a second emission layer, and the charge generation layer may be between the first light-emitting stack and the second light-emitting stack.

In one or more embodiments, the first light-emitting stack may include a first hole transport region between the first electrode and the first emission layer, and a first electron transport region between the first emission layer and the charge generation layer, and the second light-emitting stack may include a second hole transport region between the charge generation layer and the second emission layer, and a second electron transport region between the second emission layer and the second electrode.

In one or more embodiments, the second electrode may be directly above (e.g., disposed on) the second electron transport region.

In one or more embodiments, the light-emitting device may further include a capping layer above the second electrode, and a refractive index of the capping layer may be about 1.6 or more for light in a wavelength range of about 550 nm or more and about 660 nm or less.

In one or more embodiments, the second electrode may be a cathode.

In one or more embodiments, the first electrode may include at least one metal selected from among Ag, Magnesium (Mg), Cu, Aluminum (AI), Platinum (Pt), Pd, Gold Au, Nickel (Ni), Neodymium (Nd), Iridium (Ir), Chromium (Cr), Lithium (Li), Calcium (Ca), Lithium Fluoride (LiF), Molybdenum (Mo), Titanium (Ti), Tungsten (W), Indium (In), Tin (Sn), and Zinc (Zn), a compound of two or more selected from among Ag, Mg, Cu, Al, Pt, Pd, Au, Ni, Nd, Ir, Cr, Li, Ca, LiF, Mo, Ti, W, In, Sn, and Zn, or at least one selected from among indium tin oxide (e.g., ITO), indium zinc oxide (e.g., IZO), zinc oxide (e.g., ZnO), and/or indium tin zinc oxide (e.g., ITZO).

In one or more embodiments, a thickness of the second electrode may be about 30 Å or more and about 120 Å or less.

In one or more embodiments, a sheet resistance of the second electrode may be about 10Ω/□ or less.

An electronic device according to one or more embodiments of the present disclosure may include a display including a display panel and providing an image, and a power supply supplying power to the display, where the display panel may include a base layer including light-emitting areas and a non-light-emitting area adjacent to the light-emitting areas, a circuit layer on the base layer, and a display device layer on the circuit layer and including light-emitting devices corresponding to the light-emitting areas, respectively, at least some of the light-emitting devices include a first electrode, a second electrode on the first electrode and including a silver (Ag)-palladium (Pd)-copper (Cu) alloy, light-emitting stacks between the first electrode and the second electrode, each of the light-emitting stacks including an emission layer, and a charge generation layer between the, based on 100 wt % of a total weight of the Ag—Pd—Cu alloy (e.g., the total alloy), about 97.9 wt % or more and about 99.9 wt % or less of Ag, about 0.01 wt % or more and less than about 0.1 wt % of Pd, and about 0.01 wt % or more and about 2.0 wt % or less of Cu.

In one or more embodiments, the electronic device may further include at least one selected from among a processor and/or a memory.

In one or more embodiments, the electronic device may include a display and may be a television, a monitor, an outdoor billboard, a personal computer, a notebook computer, a personal digital assistant, a vehicle device, a game console, a smartphone, a tablet, a smartwatch, and/or a camera.

In one or more embodiments, the light-emitting devices may include a first light-emitting device, a second light-emitting device, and a third light-emitting device, spaced apart in a direction perpendicular to a thickness direction, and the first light-emitting device may be to emit light of a first wavelength, the second light-emitting device may be to emit light of a second wavelength longer than the first wavelength, and the third light-emitting device may be to emit light of a third wavelength longer than the second wavelength.

A method according to one or more embodiments of the present disclosure may include forming a first electrode, forming a first light-emitting stack including a first emission layer on the first electrode, forming a first charge generation layer on the first light-emitting stack, forming a second light-emitting stack on the first charge generation layer, and forming a second electrode including a silver (Ag)-palladium (Pd)-copper (Cu) alloy on the second light-emitting stack, where the second electrode may include, based on 100 wt % of a total weight of the Ag—Pd—Cu alloy, about 97.9 wt % or more and about 99.9 wt % or less of Ag, about 0.01 wt % or more and less than about 0.1 wt % of Pd, and about 0.01 wt % or more and about 2.0 wt % or less of Cu, where the method may be a method for manufacturing a light-emitting device.

In one or more embodiments, the forming of the second electrode may include a sputtering process.

In one or more embodiments, the second electrode may be provided directly on the second light-emitting stack.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain aspects of the present disclosure. In the drawings:

FIG. 1 is a perspective view showing an electronic device according to one or more embodiments of the present disclosure;

FIG. 2 is an exploded perspective view of an electronic device according to one or more embodiments of the present disclosure;

FIG. 3 is a block diagram of an electronic device according to embodiments of the present disclosure;

FIG. 4 is a diagram showing electronic devices according to one or more suitable embodiments of the present disclosure;

FIG. 5 is a cross-sectional view of a display device according to one or more embodiments of the present disclosure;

FIG. 6 is a plan view of a display panel according to one or more embodiments of the present disclosure;

FIG. 7 is an enlarged plan view of a portion of a display panel according to one or more embodiments of the present disclosure;

FIG. 8 is a cross-sectional view of a display according to one or more embodiments of the present disclosure;

FIG. 9 and FIG. 10 are cross-sectional views schematically showing a light-emitting device according to one or more embodiments of the present disclosure;

FIG. 11 and FIG. 12 are cross-sectional views of a display device according to one or more embodiments of the present disclosure;

FIG. 13 is a flowchart showing a method of manufacturing a light-emitting device according to one or more embodiments of the present disclosure; and

FIGS. 14A and 14B are cross-sectional views showing some operations of a method for manufacturing a light-emitting device according to one or more embodiments of the present disclosure.

### DETAILED DESCRIPTION

In the present disclosure, it will be understood that if (e.g., when) an element (or an area, a layer, a portion, and/or the like) is referred to as being “on,” “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As utilized herein, the term “and/or” may include any and all combinations of one or more of the associated listed elements.

It will be understood that, although the terms “first,” “second,” and/or the like may be utilized herein to describe suitable elements, the elements are not to be limited by these terms. These terms are only utilized to distinguish one element, component, area, layer or section from another element, component, area, layer or section. For instance, a first element, component, area, layer or section discussed below could be termed a second element, component, area, layer or section without departing from the scope of the present disclosure. Similarly, a second element, component, area, layer or section could be termed a first element, component, area, layer or section. In the present disclosure, the singular expressions “a,” “an” and “the” are intended to include the plural forms as well, unless the context clearly indicates otherwise.

In addition, the terms “below,” “under,” “on the lower side,” “above,” “over,” “on the upper side,” and/or the like may be utilized to describe the relationships between the elements illustrated in the drawings. These terms are relative concepts and are described on the basis of the directions indicated in the drawings.

It will be further understood that the terms “comprise, include, have,” “comprises, includes, has,” and/or “comprising, including, having”, if (e.g., when) utilized in the present disclosure, may indicate the presence of stated aspects, numbers, steps, operations, elements, components or combinations thereof, but do not preclude the possibility of the presence or addition of one or more other aspects, numbers, steps, operations, elements, components, and/or combinations thereof. It will be understood that if (e.g., when) an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, if (e.g., when) an element or layer is referred to as being “directly on,” “directly connected to”, “directly coupled to”, or “immediately adjacent to” another element or layer, there are no intervening elements or layers present.

It will be understood that if (e.g., when) a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that if (e.g., when) a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

Unless otherwise defined, all terms (including technical and scientific terms) utilized herein have the same meaning as commonly understood by one of ordinary skill in the art to which this disclosure belongs. It will be further understood that terms, such as those defined in commonly utilized dictionaries, should be interpreted as having a meaning that may be consistent with their meaning in the context of the relevant art and will not be interpreted in an idealized or overly formal sense unless expressly so defined herein.

Hereinafter, embodiments of the present disclosure will be described with reference to the drawings.

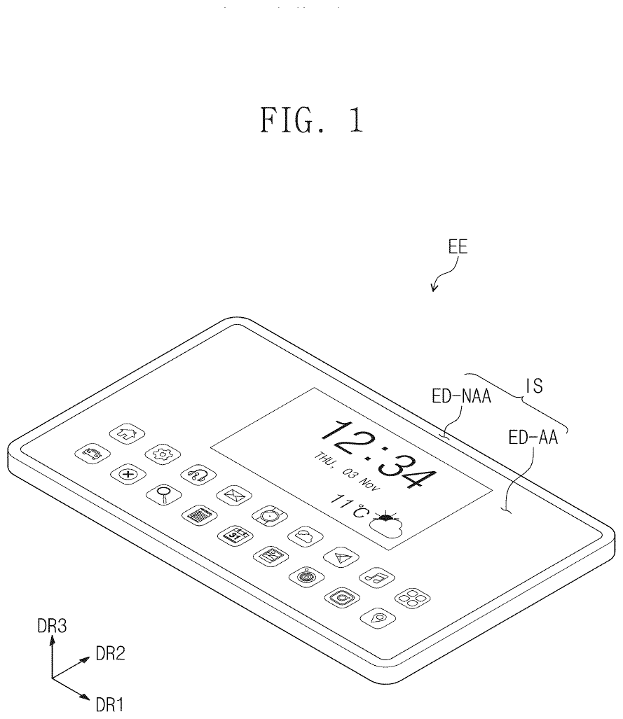

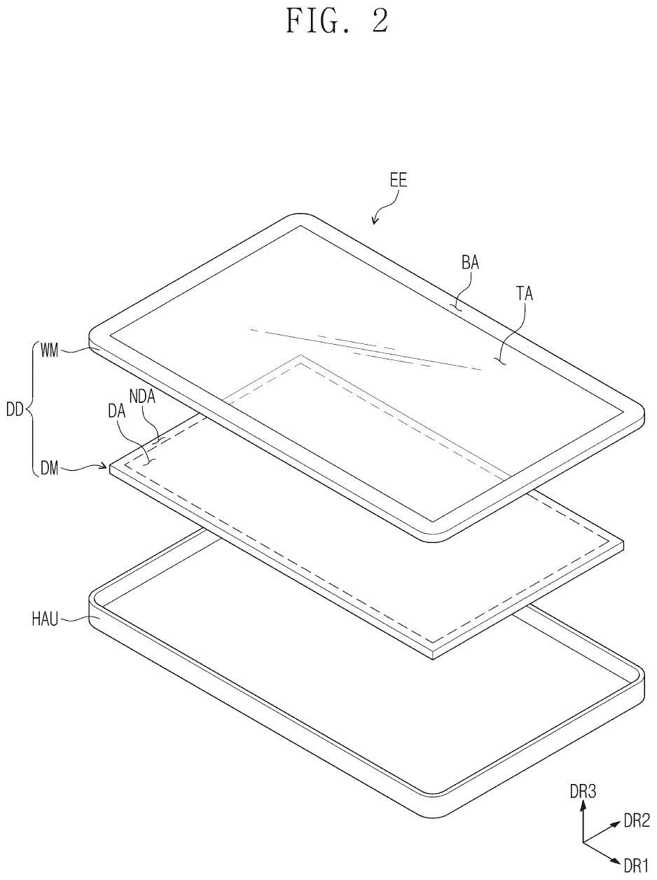

FIG. 1 is a perspective view of an electronic device according to one or more embodiments of the present disclosure. FIG. 2 is an exploded perspective view of an electronic device according to one or more embodiments of the present disclosure.

An electronic device EE according to one or more embodiments may be a display device that may be activated according to an electrical signal and display an image. The electronic device EE may include one or more suitable embodiments. For example, the electronic device EE may include large-sized devices such as a television and an outdoor billboard, as well as small and medium-sized devices such as a monitor, a mobile phone, a tablet computer, a navigation device and/or a game console. One or more embodiments of the electronic device EE may be illustrations and may not be limited to any one unless deviate from the concept of the present disclosure.

FIG. 1 and the drawings may illustrate a first direction DR1 to a third direction DR3, and the directions indicated by the first to third directions DR1, DR2 and DR3 described in the present disclosure may be relative concepts and may be converted into other directions.

In the present disclosure, the thickness direction of the electronic device EE may be a direction parallel to the third direction DR3 that may be a normal direction (e.g., a perpendicular direction) to a plane defined by the first direction DR1 and the second direction DR2. In the present disclosure, the front (or top surface) and the back (or bottom surface) of the members/parts constituting the electronic device EE may be defined based on the third direction DR3.

The electronic device EE may display an image IM in the third direction DR3 through a display surface IS parallel to the plane defined by the first direction DR1 and the second direction DR2. The third direction DR3 may be parallel to the normal direction of the display surface IS. The display surface IS on which the image IM may be displayed may correspond to the front of the electronic device EE. The image IM may include a still image and/or a dynamic image. FIG. 1 may illustrate icon images as one or more embodiments of the image IM.

In the present disclosure, “on a plane” may be defined as a state viewed from the third direction DR3. In the present disclosure, “on a cross-section” may be defined as a state viewed from the first direction DR1 or the second direction DR2. The directions indicated by the first to third directions DR1, DR2 and DR3 may be relative concepts and may be converted into other directions.

In FIG. 1, an electronic device EE having a flat display surface IS may be illustrated. However, the shape of the display surface IS of the electronic device EE may not be limited thereto and may be curved or three-dimensional.

The electronic device EE may be flexible. The term “flexible” may refer to a characteristic that may be bent and may include all from a completely foldable structure to a structure that may be bent to a level of several nanometers. For example, a flexible electronic device EE may include a curved electronic device and/or a foldable electronic device.

The display surface IS of the electronic device EE may include an active area ED-AA and a peripheral area ED-NAA. The user may view the image IM through the active area ED-AA. In one or more embodiments, in FIG. 1, the active area ED-AA may be illustrated as having a rectangular shape, but not limited thereto, the active area ED-AA may have one or more suitable shapes.

The peripheral area ED-NAA may be a non-display portion that may not display an image IM. The peripheral area ED-NAA may be a portion that may have a corresponding color and blocks light. The peripheral area ED-NAA may be adjacent to the active area ED-AA. For example, the peripheral area ED-NAA may be arranged at (e.g., disposed at; located at) at least one side of the active area ED-AA, and the peripheral area ED-NAA may surround the active area ED-AA. However, in one or more embodiments, and the peripheral area ED-NAA may be adjacent to only one side of the active area ED-AA or may be arranged on (e.g., above; disposed on; located on) a side other than the front of the electronic device EE, but not limited thereto, and the peripheral area ED-NAA may not be repeated here.

The peripheral area ED-NAA according to one or more embodiments may detect an external input applied from the outside. The external input may have suitable forms such as pressure, temperature, light, and/or the like, provided from the outside. The external input may include not only an input that may contact the electronic device EE (for example, being contacted by a user's hand and/or pen), but also an input that may be applied in proximity to the electronic device EE (for example, hovering).

Referring to FIG. 2, the electronic device EE may include a display device DD and a housing HAU. The display device DD may include a display module DM and a window WM disposed on the display module DM. The display device DD and the housing HAU may be combined to define the appearance of the electronic device EE. The housing HAU may provide an internal space capable of accommodating members/parts such as the display module DM.

The window WM may be disposed on the display module DM. The window WM may protect the display module DM from external impact. The front of the window WM may correspond to the display surface IS of the electronic device EE described above. The front of the window WM may include a transparent area TA and a bezel area BA.

The transparent area TA of the window WM may be an optically transparent area. The window WM may be to transmit an image provided by the display module DM through the transparent area TA, and the user may view the image. The transparent area TA may correspond to the active area ED-AA of the electronic device EE.

The window WM may include an optically transparent insulating material. For example, the window WM may include glass, sapphire, and/or plastic. The window WM may have a single-layer or multi-layer structure. The window WM may further include functional layers, such as an anti-fingerprint layer, a phase control layer, and/or a hard coating layer, which may be disposed on an optically transparent substrate.

The bezel area BA of the window WM may be provided as an area on which a material including a corresponding color may be deposited, coated, and/or printed. The bezel area BA of the window WM may prevent or reduce a configuration of the display module DM disposed to overlap the bezel area BA from being viewed from the outside. The bezel area BA may correspond to the peripheral area ED-NAA of the electronic device EE.

The display module DM may display an image according to an electrical signal. The display module DM may include a display area DA and a non-display area NDA adjacent to the display area DA.

The display area DA may be a portion corresponding to the active area ED-AA of the electronic device EE. The display area DA may be an area activated according to an electrical signal. The display area DA may be an area that may be to emit an image provided by the display module DM. The display area DA of the display module DM may correspond to the above-described transparent area TA. In the present disclosure, “area/portion and area/portion correspond” may refer to “overlapping each other” and may not be limited to having the same area and/or the same shape. The image displayed in the display area DA may be viewed from the outside through the transparent area TA.

The non-display area NDA may be adjacent to the display area DA. For example, the non-display area NDA may surround the display area DA. However, one or more embodiments of the present disclosure may not be limited thereto, and the non-display area NDA may be defined in suitable shapes. The non-display area NDA may be a portion corresponding to the peripheral area ED-NAA of the electronic device EE. The non-display area NDA may be an area where a driving circuit for driving the display area DA, suitable signal lines providing electrical signals, and pads may be disposed. The non-display area NDA of the display DM may correspond to the bezel area BA described above. The configurations of the display DM disposed in the non-display area NDA may be prevented or reduced from being externally recognized by the bezel area BA.

The housing HAU may be disposed under the display module DM to accommodate the display module DM. The housing HAU may absorb impact applied from the outside and may protect the display module DM by preventing or reducing foreign substances/moisture, and/or the like from penetrating into the display module DM. In one or more embodiments, the housing HAU may be provided in a form in which a plurality of storage devices may be combined.

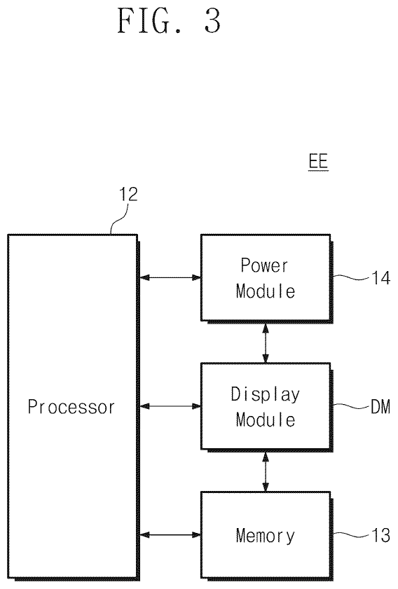

FIG. 3 is a block diagram of an electronic device EE according to one or more embodiments of the present disclosure.

An electronic device EE according to one or more embodiments may include a display module DM (e.g., a display), a processor 12, a memory 13, and a power module 14 (e.g., a power supply).

The processor 12 may include at least one selected from among a central processing unit (CPU), an application processor (AP), a graphic processing unit (GPU), a communication processor (CP), an image signal processor (ISP), and/or a controller.

The power module 14 may include a power supply device such as a power adapter and/or a battery device, and a power conversion device that may convert power supplied by the power supply device to generate power suitable for the operation of the electronic device EE.

The memory 13 may store data information suitable for the operation of the processor 12 or the display module DM. If (e.g., when) the processor 12 may execute an application stored in the memory 13, an image data signal and/or an input control signal may be transmitted to the display module DM, and the display module DM may process the received signal and output image information through a display screen.

At least one of the components of the electronic device EE may be included in the display device DD (shown in FIG. 2) according to one or more embodiments. In addition, some of the individual devices that may be functionally included in one device among the components of the electronic device EE may be included in the display device DD (shown in FIG. 2), and other parts may be provided separately from the display device DD (shown in FIG. 2). For example, the display device DD (shown in FIG. 2) may include the display module DM, and the processor 12, the memory 13 and the power module 14 may be provided in the form of other devices within the electronic device EE other than the display device DD (shown in FIG. 2).

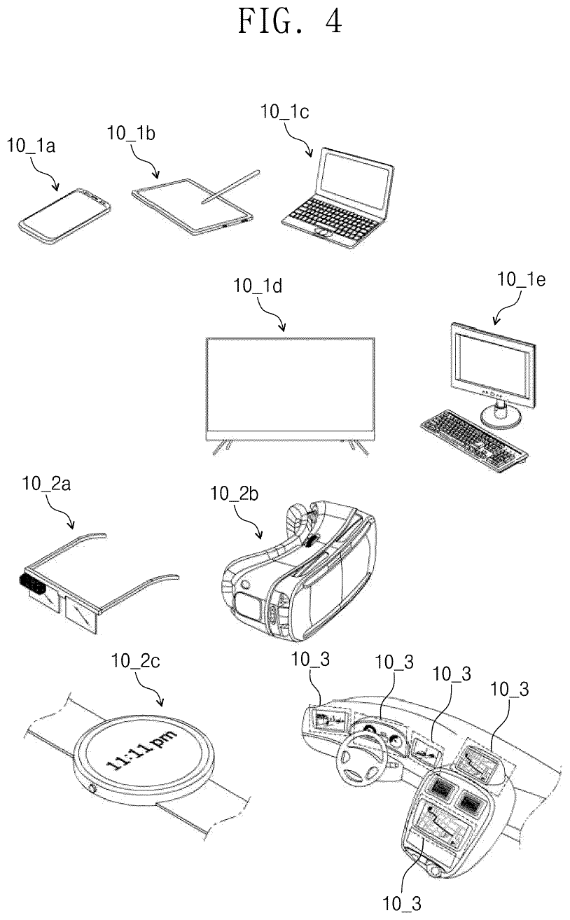

FIG. 4 is a diagram schematically showing electronic devices according to one or more suitable embodiments. Referring to FIG. 4, an electronic device including the display device DD (shown in FIG. 2) according to one or more embodiments may include not only electronic devices for displaying images such as a smart phone 10_1a, a tablet PC 10_1b, a laptop 10_1c, a TV 10_1d, and a desk monitor 10_1e, but also wearable electronic devices including the display module DM (shown in FIG. 3) such as smart glasses 10_2a, a head-mounted display 10_2b, and a smart watch 10_2c, and vehicle electronic devices 10_3 including the display module DM (shown in FIG. 3) such as a dashboard of a car, center fascia, a Center Information Display (CID) disposed on a dashboard, and/or a room mirror display.

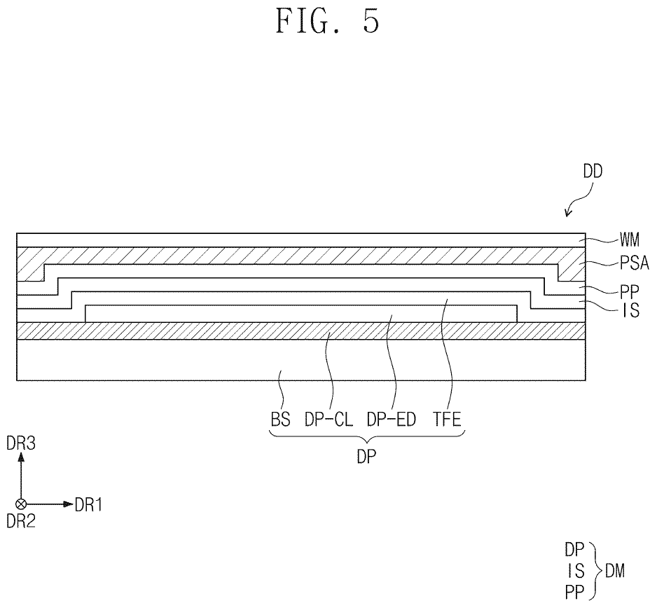

FIG. 5 is a cross-sectional view of a display device DD according to one or more embodiments of the present disclosure.

The display device DD may include a display module DM and a window WM disposed on the display module DM. The display module DM and the window WM may be joined by an adhesive layer PSA. According to one or more embodiments of the present disclosure, the window WM may be provided (e.g., formed) by a coating method, and the window WM may be in contact with the display module DM. In embodiments, the adhesive layer PSA may not be repeated.

The display module DM may include a display panel DP, an input sensor IS, and an optical layer PP. The display panel DP may include a base layer BS, a circuit layer DP-CL, a display device layer DP-ED, and an encapsulation layer TFE.

The circuit layer DP-CL may be disposed on the top surface of the base layer BS. The base layer BS may be a flexible substrate capable of bending, folding, rolling, and/or the like. The base layer BS may be a glass substrate, a metal substrate, a polymer substrate, and/or the like. However, one or more embodiments of the present disclosure may not be limited thereto, and the base layer BS may be an inorganic layer, an organic layer, and/or a composite material layer. In fact, the base layer BS may have the same shape as the display panel DP.

The base layer BS may have a multilayer structure. For example, the base layer BS may include a first synthetic resin layer, a second synthetic resin layer, and inorganic layers disposed therebetween. Each of the first and second synthetic resin layers may include a polyimide-based resin and may not be limited.

The circuit layer DP-CL may be disposed on the base layer BS. The circuit layer DP-CL may include a plurality of insulating layers, a plurality of semiconductor patterns, a plurality of conductive patterns, and/or signal lines. The circuit layer DP-CL may include a driving circuit of a pixel.

The display device layer DP-ED may be disposed on the circuit layer DP-CL. The display device layer DP-ED may include a light-emitting device. For example, the light-emitting device may include an organic light-emitting material, an inorganic light-emitting material, an organic-inorganic light-emitting material, a quantum dot, a quantum rod, a micro LED, and/or a nano LED.

The encapsulation layer TFE may be disposed on the display device layer DP-ED. The encapsulation layer TFE may protect the display device layer DP-ED, for example, the light-emitting device, from foreign substances such as moisture, oxygen, and dust particles. The encapsulation layer TFE may include at least one encapsulation inorganic layer. The encapsulation layer TFE may include a stacked structure of a first encapsulation inorganic layer/an encapsulation organic layer/a second encapsulation inorganic layer. For example, the stacked structure may be a structure including the first encapsulation inorganic layer, the encapsulation organic layer, and the second encapsulation inorganic layer stacked together.

An input sensor IS may be directly disposed on the display panel DP. The input sensor IS may detect a user's input, for example, by an electromagnetic induction method and/or a capacitive method. The display panel DP and the input sensor IS may be provided through a continuous process. Here, “directly disposed” may refer to that no third component may be disposed between the input sensor IS and the display panel DP. For example, a separate adhesive layer may not be disposed between the input sensor IS and the display panel DP. The input sensor IS may not be repeated in the display device DD according to one or more embodiments of the present disclosure.

The optical layer PP may reduce the reflectivity of external light incident from the upper side of the window WM. The optical layer PP according to one or more embodiments of the present disclosure may include a phase retarder and a polarizer. The phase retarder may be a film type or a liquid crystal coating type and may include a A/2 phase retarder and/or a A/4 phase retarder. The polarizer may also be a film type or a liquid crystal coating type. The film type may include a stretchable synthetic resin film, and the liquid crystal coating type may include liquid crystals aligned in a set array. The phase retarder and the polarizer may further include a protective film. The phase retarder and the polarizer themselves or the protective film may be defined as the base layer of the optical layer PP.

The optical layer PP according to one or more embodiments of the present disclosure may include color filters. The color filters may have a corresponding arrangement. The arrangement of the color filters may be determined in consideration of the emission colors of the pixels included in the display panel DP. The optical layer PP may further include a black matrix adjacent to the color filters.

The window WM according to one or more embodiments of the present disclosure may include a base layer and a light-shielding pattern. The base layer may include a glass substrate and/or a synthetic resin film or the like. The light-shielding pattern may partially overlap the base layer WP-BS. The light-shielding pattern may be disposed on the back of the base layer, and the light-shielding pattern may substantially define a bezel area DD-NDA (shown in FIG. 1) of the electronic device EE. An area where the light-shielding pattern may not be disposed may define an image area DD-DA (shown in FIG. 1) of the electronic device EE.

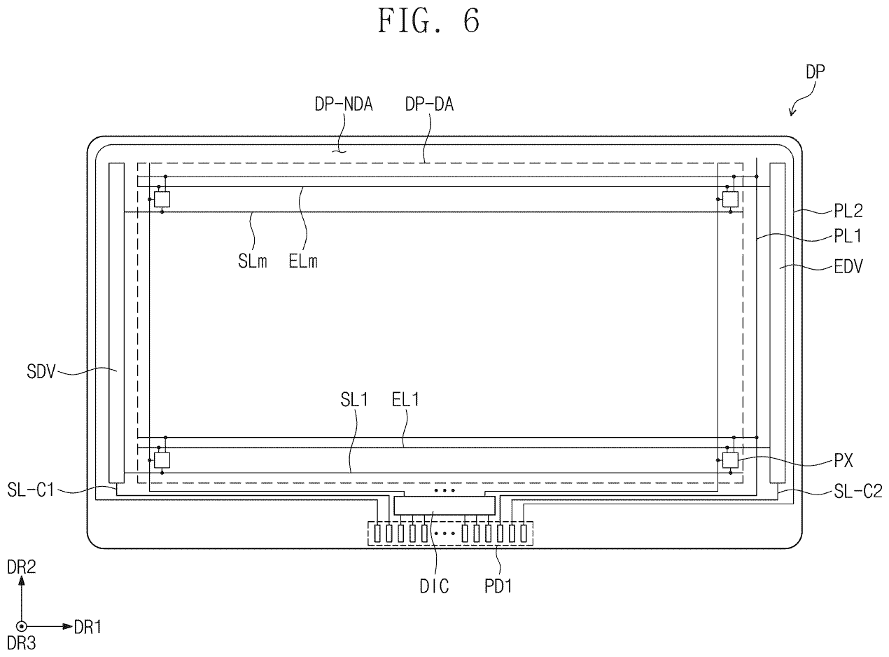

FIG. 6 is a plan view of a display panel DP according to one or more embodiments of the present disclosure.

Referring to FIG. 6, a display panel DP may include a plurality of pixels PX, a scan driving circuit SDV, a light-emitting driving circuit EDV, a plurality of signal lines, and a plurality of pads PD. A plurality of pixels PX may be disposed in a display area DP-DA. A driving chip DIC mounted in a non-display area DP-NDA may include a data driving circuit. The display area DP-DA may correspond to the image area DD-DA of FIG. 1, and the non-display area DP-NDA may correspond to the bezel area DD-NDA. In the present disclosure, “area or portion and area or portion correspond” may refer to overlapping, and may not be suitably limited to two different areas or portions having the same area. In one or more embodiments, the data driving circuit may also be integrated into the display panel DP like the scan driving circuit SDV and the light-emitting driving circuit EDV.

The plurality of signal lines may include a plurality of scan lines SL1 to SLm, a plurality of data lines DL1 to DLn, a plurality of light-emitting lines EL1 to ELm, first and second control lines SL-C1, and SL-C2, and first and second power lines PL1, and PL2. In one or more embodiments, m and n may be natural numbers of 2 or more.

The scan lines SL1 to SLm may be to extend in the first direction DR1 and be electrically connected to the pixels PX and the scan driving circuit SDV. The data lines DL1 to DLn may be to extend in the second direction DR2 and be electrically connected to the pixels PX and the driving chip DIC. The light-emitting lines EL1 to ELm may be extended in the first direction DR1 and electrically connected to the pixels PX and the light-emitting driving circuit EDV.

The first power line PL1 may receive a first power voltage, and the second power line PL2 may receive a second power voltage having a lower level than the first power voltage. In embodiments, the second electrode (for example, a cathode) of the light-emitting device may be coupled to (e.g., connected to) the second power line PL2.

The first control line SL-C1 may be connected to the scan driving circuit SDV and may be extended toward the bottom of the display panel DP. The second control line SL-C2 may be connected to the light-emitting driving circuit EDV and may be extended toward the bottom of the display panel DP. The pads PD may be disposed in a non-display area DP-NDA adjacent to the bottom of the display panel DP and may be closer to the bottom of the display panel DP than the driving chip DIC. The pads PD may be connected to the driver chip DIC and some signal lines.

The scan driving circuit SDV may generate a plurality of scan signals, and the scan signals may be applied to the pixels PX through the scan lines SL1 to SLm. The driver chip DIC may generate a plurality of data voltages, and the data voltages may be applied to the pixels PX through the data lines DL1 to DLn. The light-emitting driving circuit EDV may generate a plurality of light-emitting signals, and the light-emitting signals may be applied to the pixels PX through the light-emitting lines EL1 to ELm. The pixels PX may be to receive the data voltages in response to the scan signals. The pixels PX may display an image by emitting light with a luminance corresponding to the data voltages in response to the light-emitting signals.

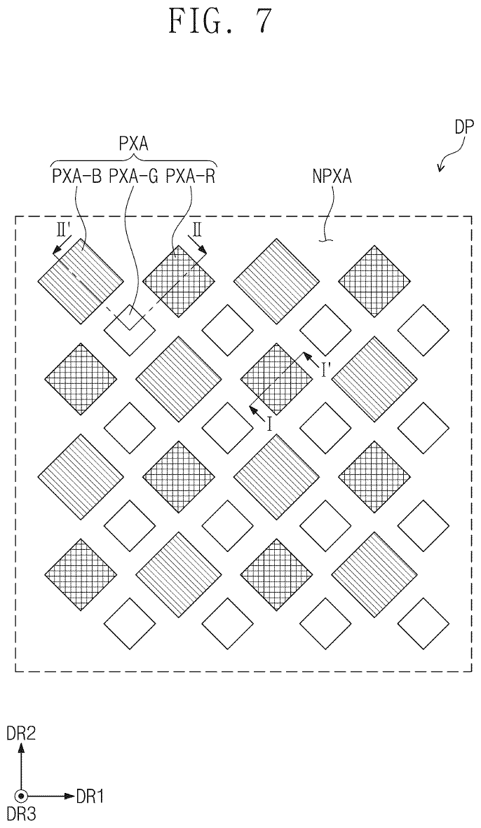

FIG. 7 is a plan view showing a display panel DP according to one or more embodiments of the present disclosure. Hereinafter, the description of the display panel DP may be equally applied to the display panel DP included in the display device DD illustrated in FIG. 1, FIG. 2, and/or the like.

Referring to FIG. 7, a display panel DP may include a light-emitting area PXA and a non-light-emitting area NPXA. The non-light-emitting area NPXA may surround the light-emitting area PXA. The light-emitting area PXA may be provided in a plurality. The light-emitting area PXA may include a red light-emitting area PXA-R, a green light-emitting area PXA-G, and a blue light-emitting area PXA-B. Each of the red light-emitting area PXA-R, the green light-emitting area PXA-G, and the blue light-emitting area PXA-B may be to emit light of a different wavelength range. The red light-emitting area PXA-R may be to emit red light, the green light-emitting area PXA-G may be to emit green light, and the blue light-emitting area PXA-B may be to emit blue light.

Among the plurality of light-emitting areas PXA-R, PXA-G, and PXA-B, the blue light-emitting area PXA-B may have the largest area, and the green light-emitting area PXA-G may have the smallest area. However, in one or more embodiments, the areas of the plurality of light-emitting areas PXA-R, PXA-G, and PXA-B may not be limited thereto. In FIG. 7, the red light-emitting area PXA-R and the blue light-emitting area PXA-B may be arranged alternately in one row, and the green light-emitting area PXA-G may be arranged in another row, spaced and/or apart (e.g., spaced apart or separated) from the red light-emitting area PXA-R and the blue light-emitting area PXA-B. However, in one or more embodiments, the arrangement of the plurality of light-emitting areas PXA-R, PXA-G, and PXA-B is not limited thereto. For example, the light-emitting areas PXA-R, PXA-G, and PXA-B may be arranged in a stripe shape. In embodiments, the arrangement of the light-emitting areas PXA-R, PXA-G, and PXA-B may have a PENTILE® arrangement structure (e.g., an RGBG matrix, RGBG structure, or RGBG matrix structure) or a DIAMOND PIXEL® arrangement structure, but the present disclosure is not limited thereto. PENTILE® and DIAMOND PIXEL® are duly registered trademarks of Samsung Display Co., Ltd.

In FIG. 7, each of the plurality of light-emitting areas PXA-R, PXA-G, and PXA-B may be illustrated as having a square shape with a different size on a plane, but one or more embodiments of the present disclosure may not be limited thereto, and the plurality of light-emitting areas PXA-R, PXA-G, and PXA-B may have suitable shapes. For example, each of the light-emitting areas PXA-R, PXA-G, and PXA-B may have a square shape with rounded corners on a plane. In embodiments, each of the light-emitting areas PXA-R, PXA-G, and PXA-B may have a circular or elliptical shape on the plane.

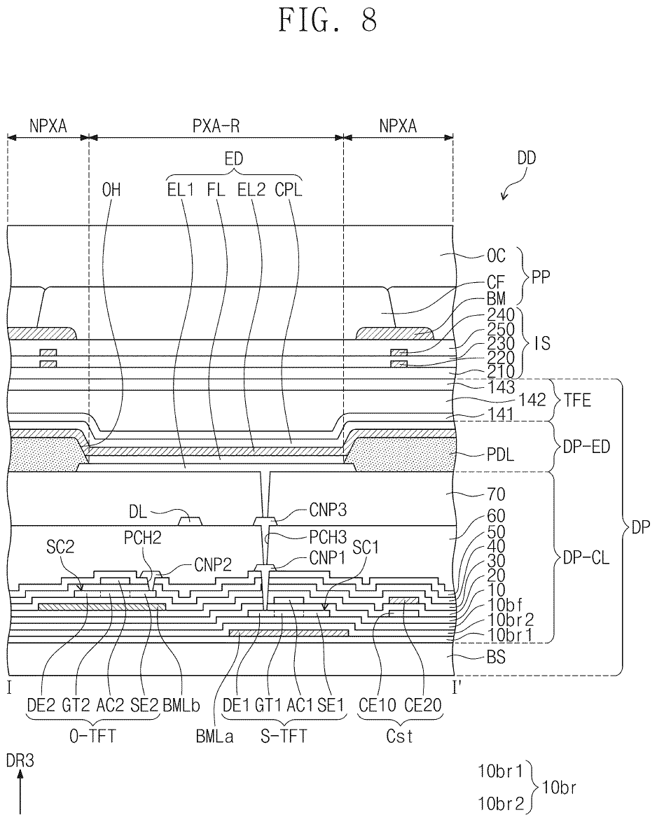

FIG. 8 is a cross-sectional view of a display device DD according to one or more embodiments of the present disclosure. FIG. 8 illustrates a cross-section of a display device DD corresponding to I-I′ in FIG. 7. In FIG. 8, some components of the display device DD, such as the adhesive layer PSA and the window WM of FIG. 5, may be omitted.

A pixel driving circuit that drives a light-emitting device ED may include a plurality of pixel driving devices. The pixel driving circuit may include a plurality of transistors S-TFT and O-TFT and a capacitor Cst. In FIG. 8, a silicon transistor S-TFT and an oxide transistor O-TFT may be illustrated as one or more embodiments of transistors. The pixel driving circuit of FIG. 8 may be one or more embodiments of the present disclosure, and the configuration of the pixel driving circuit may not be limited thereto. The pixel driving circuit may include one type of transistor selected from among the silicon transistor S-TFT and the oxide transistor O-TFT.

Referring to FIG. 8, the base layer BS is illustrated as a single layer. The base layer BS may include a synthetic resin such as polyimide. A base layer BS may be provided by the coating of a synthetic resin layer on a work substrate (or carrier substrate). If (e.g., when) the display device DD is completed by performing a subsequent process, the work substrate may be removed. In one or more embodiments, the base layer BS may have a multilayer structure including a first synthetic resin layer, at least one inorganic layer, and a second synthetic resin layer.

Referring to FIG. 8, a barrier layer 10br may be disposed on the base layer BS. The barrier layer 10br may prevent or reduce foreign substances from entering from the outside. The barrier layer 10br may include at least one inorganic layer. The barrier layer 10br may include a silicon oxide layer and a silicon nitride layer. Each of the silicon oxide layer and the silicon nitride layer may be provided in a plurality, and the silicon oxide layers and the silicon nitride layers may be alternately stacked.

The barrier layer 10br may include a lower barrier layer 10br1 and an upper barrier layer 10br2. A first shielding electrode BMLa may be disposed between the lower barrier layer 10br1 and the upper barrier layer 10br2. The first shielding electrode BMLa may be disposed to correspond to a silicon transistor S-TFT. The first shielding electrode BMLa may include a metal, for example, molybdenum.

The first shielding electrode BMLa may be to receive a bias voltage. The first shielding electrode BMLa may also be to receive a first power voltage. The first shielding electrode BMLa may block an electric potential due to a polarization phenomenon from affecting the silicon transistor S-TFT. The first shielding electrode BMLa may block external light from reaching the silicon transistor S-TFT. In one or more embodiments, the first shielding electrode BMLa may be a floating electrode that may be isolated from other electrodes or wirings.

A buffer layer 10bf may be disposed on the barrier layer 10br. The buffer layer 10bf may prevent or reduce metal atoms or impurities from diffusing from the base layer BS to the first semiconductor pattern SC1 on the upper side. The buffer layer 10bf may include at least one inorganic layer. The buffer layer 10bf may include a silicon oxide layer and a silicon nitride layer.

A first semiconductor pattern SC1 may be disposed on the buffer layer 10bf.

The first semiconductor pattern SC1 may include a silicon semiconductor. For example, the silicon semiconductor may include amorphous silicon, polycrystalline silicon, and/or the like. For example, the first semiconductor pattern SC1 may include low-temperature polysilicon.

The electrical properties of the first semiconductor pattern SC1 may suitably vary depending on whether doped or not. The first semiconductor pattern SC1 may include a first region having high conductivity and a second region having low conductivity. The first region may be doped with an N-type dopant or a P-type dopant.

The second region may be an undoped region or a region doped at a lower concentration than the first region. The source region SE1, the channel region AC1 (or active region), and the drain region DE1 of the silicon transistor S-TFT may be provided from the first semiconductor pattern SC1. The source region SE1 and the drain region DE1 may be to extend in opposite directions from the channel region AC1 on a cross-section.

A first insulating layer 10 may be disposed on the buffer layer 10bf. The first insulating layer 10 may cover the first semiconductor pattern SC1. The first insulating layer 10 may be an inorganic layer. The first insulating layer 10 may be a single-layer silicon oxide layer. The inorganic layer of the driving device layer 120 described later, as well as the first insulating layer 10, may have a single-layer or multi-layer structure and may include at least one of the materials described above, but one or more embodiments of the present disclosure may not be limited thereto.

A gate GT1 of a silicon transistor S-TFT may be disposed on the first insulating layer 10. The gate GT1 may be a portion of a metal pattern. The gate GT1 may overlap the channel region AC1. In the process of doping the first semiconductor pattern SC1, the gate GT1 may act as a mask. A first electrode CE10 of a storage capacitor Cst may be disposed on the first insulating layer 10. In one or more embodiments, the first electrode CE10 may have an integral shape with the gate GT1.

A second insulating layer 20 may be disposed on the first insulating layer 10 and may cover the gate GT1. In one or more embodiments, an upper electrode overlapping the gate GT1 may be further disposed on the second insulating layer 20. A second electrode CE20 overlapping the first electrode CE10 may be disposed on the second insulating layer 20. The upper electrode may have an integral shape with the second electrode CE20 on a plane.

A second shielding electrode BMLb may be disposed on the second insulating layer 20. The second shielding electrode BMLb may be disposed to correspond to the oxide transistor O-TFT. In one or more embodiments, the second shielding electrode BMLb may not be repeated. According to one or more embodiments of the present disclosure, the first shielding electrode BMLa may be to extend to the bottom of the oxide transistor O-TFT to replace the second shielding electrode BMLb.

A third insulating layer 30 may be disposed on the second insulating layer 20. The second semiconductor pattern SC2 may be disposed on the third insulating layer 30. The second semiconductor pattern SC2 may include a channel region AC2 of the oxide transistor O-TFT. The second semiconductor pattern SC2 may include a metal oxide semiconductor. The second semiconductor pattern SC2 may include a transparent conductive oxide (e.g., TCO), such as indium tin oxide (e.g., ITO), indium zinc oxide (e.g., IZO), indium gallium zinc oxide (e.g., IGZO), zinc oxide (e.g., ZnOₓ), and/or indium oxide (e.g., In₂O₃).

The metal oxide semiconductor may include a plurality of regions SE2, AC2, and DE2 that may be distinguished depending on whether the transparent conductive oxide may be reduced. The region where the transparent conductive oxide may be reduced (hereinafter, referred to as a reduced region) may have greater conductivity than the region where the transparent conductive oxide may not be reduced (hereinafter, referred to as a non-reduced region). The reduced region substantially may serve as a source/drain or a signal line of the transistor. The non-reduced region substantially may correspond to the semiconductor region (or channel) of the transistor. A fourth insulating layer 40 may be disposed on the third insulating layer 30.

As illustrated in FIG. 8, the fourth insulating layer 40 may cover the second semiconductor pattern SC2. In one or more embodiments, the fourth insulating layer 40 may be an insulating pattern that may overlap the gate GT2 of the oxide transistor O-TFT and expose the source region SE2 and the drain region DE2 of the oxide transistor O-TFT.

A gate GT2 of the oxide transistor O-TFT may be disposed on the fourth insulating layer 40. The gate GT2 of the oxide transistor O-TFT may be a portion of the metal pattern. The gate GT2 of the oxide transistor O-TFT may overlap the channel region AC2. A fifth insulating layer 50 may be disposed on the fourth insulating layer 40, and the fifth insulating layer 50 may cover the gate GT2. Each of the first insulating layer 10 to the fifth insulating layer 50 may be an inorganic layer.

A first connection pattern CNP1 and a second connection pattern CNP2 may be disposed on the fifth insulating layer 50. Because the first connection pattern CNP1 and the second connection pattern CNP2 may be provided through the same process, the first connection pattern CNP1 and the second connection pattern CNP2 may have the same material and the same stacked structure. The first connection pattern CNP1 may be connected to the drain region DE1 of the silicon transistor S-TFT through a first pixel contact hole PCH1 penetrating the first to fifth insulating layers 10, 20, 30, 40, and 50. The second connection pattern CNP2 may be connected to the source region SE2 of the oxide transistor O-TFT through a second pixel contact hole PCH2 penetrating the fourth and fifth insulating layers 40, and 50. The connection relationship of the first connection pattern CNP1 and the second connection pattern CNP2 for the silicon transistor S-TFT and the oxide transistor O-TFT may not be limited thereto.

A sixth insulating layer 60 may be disposed on the fifth insulating layer 50. A third connection pattern CNP3 may be disposed on the sixth insulating layer 60. The third connection pattern CNP3 may be connected to the first connection pattern CNP1 through a third pixel contact hole PCH3 penetrating the sixth insulating layer 60. A data line DL may be disposed on the sixth insulating layer 60. A seventh insulating layer 70 may be disposed on the sixth insulating layer 60 and may cover the third connection pattern CNP3 and the data line DL. The third connection pattern CNP3 and the data line DL may be provided through the same process and may have substantially the same material and substantially the same stacked structure. Each of the sixth insulating layer 60 and the seventh insulating layer 70 may be an organic layer.

A light-emitting device ED may include a first electrode EL1, a functional layer FL, and a second electrode EL2. The first electrode EL1 of the light-emitting device ED may be disposed on the seventh insulating layer 70. The first electrode EL1 may be a (semi)transparent electrode or a reflective electrode. The first electrode EL1 may include a sequentially stacked ITO/Ag/ITO stacked structure. For example, the first electrode EL1 may have a stacked structure including a layer of ITO, a layer of Ag, and a layer of ITO stacked in order. The positions of the first electrode EL1 and the second electrode EL2 may be interchanged.

The pixel defining layer PDL may be disposed on the seventh insulating layer 70. The pixel defining layer PDL may be an organic layer. The pixel defining layer PDL may have a property of absorbing light, and for example, the pixel defining layer PDL may have a black color. The pixel defining layer PDL may include a black component (e.g., a black coloring agent). The black component may include a black dye or a black pigment. The black component may include carbon black, a metal such as chromium, and/or an oxide thereof. The pixel defining layer PDL may correspond to a light-shielding pattern having light-shielding properties.

The pixel defining layer PDL may cover a portion of the first electrode EL1. For example, an opening part OH exposing a portion of the first electrode EL1 may be defined in the pixel defining layer PDL. A light-emitting area PXA-R may be defined to correspond to the opening part OH. In FIG. 8, one light-emitting area PXA-R corresponding to the red light-emitting area PXA-R of FIG. 7 may be illustrated. The cross-sections corresponding to the green light-emitting area PXA-G and the blue light-emitting area PXA-B of FIG. 7 may also be substantially the same as those illustrated in FIG. 7. However, a functional layer FL of a different material from the red light-emitting area PXA-R may be disposed in the green light-emitting area PXA-G and the blue light-emitting area PXA-B.

In one or more embodiments, the functional layer FL may include at least an emission layer. The functional layer FL may include a plurality of emission stacks, each of which may include an emission layer, and a charge generation layer disposed between the plurality of emission stacks, which will be described later.

The light-emitting device ED according to one or more embodiments may further include a capping layer CPL. The capping layer CPL may be disposed on the second electrode EL2 and may be for improving the light extraction efficiency generated from the emission layer of the light-emitting device ED.

The encapsulation layer TFE may cover the light-emitting device ED. The encapsulation layer TFE may include a first encapsulation inorganic layer 141, an encapsulation organic layer 142, and a second encapsulation inorganic layer 143 that are sequentially stacked, but the layers constituting the encapsulation layer TFE may not be limited thereto. The encapsulation inorganic layers 141 and 143 may include a silicon nitride layer, a silicon oxynitride layer, a silicon oxide layer, a titanium oxide layer, and/or an aluminum oxide layer. Each of the encapsulation inorganic layers 141 and 143 may have a multilayer structure. The encapsulating organic layer 142 may include an acrylic organic layer and/or an epoxy-based organic layer, but one or more embodiments of the present disclosure may not be limited thereto. The encapsulating organic layer 142 may include a photopolymerizable organic material. The first encapsulating inorganic layer 141 may be directly disposed on the capping layer CPL of the light-emitting device ED.

The input sensor IS may include a plurality of conductive patterns. The input sensor IS may include at least one conductive layer (or at least one sensor conductive layer) including a plurality of conductive patterns, and at least one insulating layer (or at least one sensor insulating layer). In one or more embodiments, the input sensor IS may include a first insulating layer 210 (or a first sensor insulating layer), a first conductive layer 220 (or a first sensor conductive layer), a second insulating layer 230 (or a second sensor insulating layer), a second conductive layer 240 (or a second sensor conductive layer), and/or a third insulating layer 250 (or a third sensor insulating layer). FIG. 8 schematically illustrates a plurality of conductive patterns included in each of the first conductive layer 220 and the second conductive layer 240.

The first insulating layer 210 may be directly disposed on the display panel DP. The first insulating layer 210 may be an inorganic layer including at least one selected from among silicon nitride, silicon oxynitride, and/or silicon oxide. Each of the first conductive layer 220 and the second conductive layer 240 may have a single layer structure or a multi-layer structure stacked along the third direction DR3. The first conductive layer 220 and the second conductive layer 240 may include conductive lines defining a mesh-shaped electrode. The conductive lines of the first conductive layer 220 and the conductive lines of the second conductive layer 240 may or may not be connected through a contact hole penetrating the second insulating layer 230 depending on the location.

The first conductive layer 220 and the second conductive layer 240 of the single layer structure may include a metal layer or a transparent conductive layer. The metal layer may include molybdenum, silver, titanium, copper, aluminum, and/or an alloy thereof. The transparent conductive layer may include a transparent conductive oxide such as indium tin oxide (e.g., ITO), indium zinc oxide (e.g., IZO), zinc oxide (e.g., ZnOₓ), and/or indium zinc tin oxide (e.g., IZTO). In addition, the transparent conductive layer may include a conductive polymer such as poly(3,4-ethylenedioxythiophene) (PEDOT), a metal nanowire, graphene, and/or the like.

The first conductive layer 220 and the second conductive layer 240 of the multilayer structure may include metal layers. The metal layers may have a three-layer structure of, for example, titanium/aluminum/titanium. For example, the three-layer structure may have a layer of titanium, a layer of aluminum, and a layer of titanium. The conductive layer with a multilayer structure may include at least one metal layer and at least one transparent conductive layer. The second insulating layer 230 may be disposed between the first conductive layer 220 and the second conductive layer 240. The second insulating layer 230 disposed between the first conductive layer 220 and the second conductive layer 240 may be described as a “sensing insulating layer” in the present disclosure. The third insulating layer 250 may cover the second conductive layer 240. In one or more embodiments, the third insulating layer 250 may not be repeated. The second insulating layer 230 and the third insulating layer 250 may include an inorganic layer or an organic layer.

The optical layer PP may be disposed on the input sensor IS. The optical layer PP may include a light-shielding pattern BM, a color filter CF, and a planarization layer OC.

The material constituting the light-shielding pattern BM may not be limited as long as it is a material that absorbs light. The light-shielding pattern BM may be a layer having a black color, and in one or more embodiments, the light-shielding pattern BM may include a black component (e.g., a black coloring agent). The black component may include a black dye or a black pigment. The black component may include carbon black, a metal such as chromium, and/or an oxide thereof.

The light-shielding pattern BM may overlap the first conductive layer 220 and the second conductive layer 240 on a plane. The light-shielding pattern BM may prevent or reduce the reflection of external light by the first conductive layer 220 and the second conductive layer 240. The light-shielding pattern BM may overlap the non-light-emitting area NPXA.

The color filter CF may overlap at least the light-emitting area PXA-R. A portion of the color filter CF may overlap the non-light-emitting area NPXA. A portion of the color filter CF may be disposed on the light-shielding pattern BM. The color filter CF may transmit light generated from the light-emitting device ED and block some wavelength bands of external light. The color filter CF may reduce the reflection of external light by the first electrode EL1 and the second electrode EL2.

The planarization layer OC may cover the light-shielding pattern BM and the color filter CF. The planarization layer OC may include an organic material, and the planarization layer OC may provide a flat top surface.

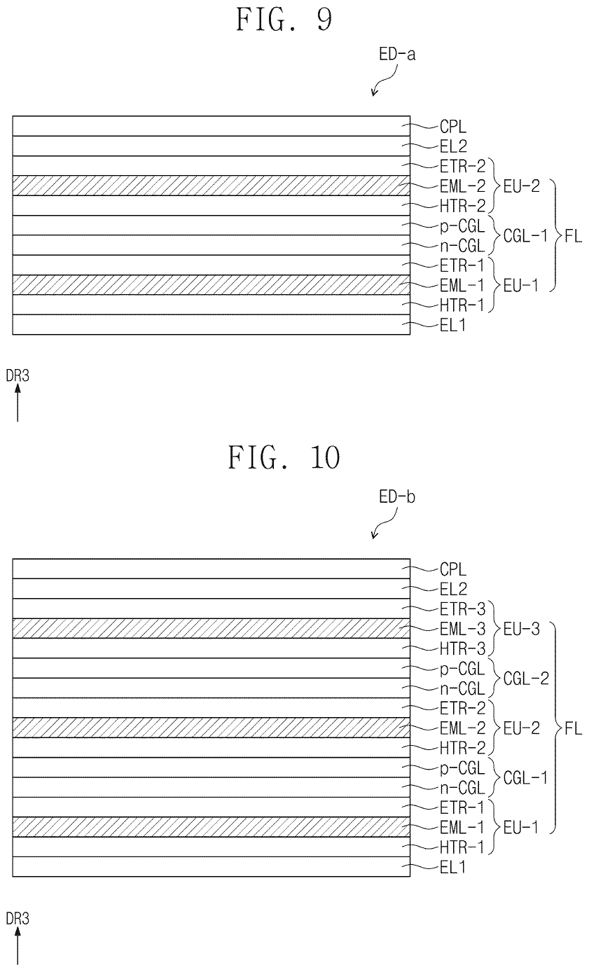

FIGS. 9 and 10 are cross-sectional views schematically showing a light-emitting device according to one or more embodiments of the present disclosure.

Referring to FIGS. 9 and 10, the light-emitting devices ED-a and ED-b may include a first electrode EL1, a second electrode EL2 facing the first electrode EL1, and a functional layer FL disposed between the first electrode EL1 and the second electrode EL2. The functional layer FL may include a plurality of light-emitting stacks. The plurality of light-emitting stacks may include at least two light-emitting stacks. For example, the light-emitting devices ED-a and ED-b may include two light-emitting stacks EU-1 and EU-2 as illustrated in FIG. 9 or may include three light-emitting stacks EU-1, EU-2 and EU-3 as illustrated in FIG. 10. The plurality of light-emitting stacks may be sequentially stacked and disposed between the first electrode EL1 and the second electrode EL2. However, one or more embodiments of the present disclosure may not be limited thereto, and the light-emitting device according to one or more embodiments may include four or more light-emitting stacks.

Hereinafter, with reference to FIGS. 9 and 10, light-emitting devices ED-a and ED-b including two light-emitting stacks and three light-emitting stacks will be described in detail. FIG. 9 illustrates one or more embodiments of a light-emitting device ED-a including two stacked light-emitting stacks between a first electrode EL1 and a second electrode EL2. FIG. 10 illustrates one or more embodiments of a light-emitting device ED-b including three stacked light-emitting stacks between a first electrode EL1 and a second electrode EL2.

Referring to FIG. 9, the light-emitting device ED-a according to one or more embodiments may include a first light-emitting stack EU-1 and a second light-emitting stack EU-2 that may be sequentially stacked. Each of the first light-emitting stack EU- and the second light-emitting stack EU-2 may include emission layers EML-1 and EML2, respectively. For example, the light-emitting device ED-a according to one or more embodiments may be a light-emitting device having a tandem structure including a plurality of emission layers.

In the light-emitting device ED-a according to one or more embodiments, a first hole transport region HTR-1 may be disposed between the first electrode EL1 and the first emission layer EML-1, and a first electron transport region ETR-1 may be disposed between the first emission layer EML-1 and the first charge generation layer CGL-1. A second hole transport region HTR-2 may be disposed between the first charge generation layer CGL-1 and the second emission layer EML-2, and a second electron transport region ETR-2 may be disposed between the second electrode EL2 and the second emission layer EML-2. In one or more embodiments, the light-emitting device ED-a may be to emit light from the first electrode EL1 toward the second electrode EL2. The light-emitting device ED-a according to one or more embodiments may illustrate a structure in which, based on the direction emitting light, the hole transport regions HTR-1 and HTR-2 may be disposed below the plurality of light-emitting stacks EU-1 and EU-2, and the electron transport regions ETR-1 and ETR-2 may be disposed above the plurality of light-emitting stacks EU-1 and EU-2. However, one or more embodiments of the present disclosure may not be limited thereto and may have an inverted device structure in which, based on the direction emitting light, the electron transport regions ETR-1 and ETR-2 may be disposed below the plurality of light-emitting stacks EU-1 and EU-2, and the hole transport regions HTR-1 and HTR-2 may be disposed above the plurality of light-emitting stacks EU-1 and EU-2.

In the light-emitting device ED-a of one or more embodiments, each of the first and second light-emitting stacks EU-1 and EU-2 may include an emission layer and a plurality of charge control layers. The first light-emitting stack EU-1 may include a first emission layer EML-1, a first hole transport region HTR-1 disposed between the first electrode EL1 and the first emission layer EML-1, and a first electron transport region ETR-1 disposed between the first emission layer EML-1 and the first charge generation layer CGL-1. The second light-emitting stack EU-2 may include a second emission layer EML-2, a second hole transport region HTR-2 disposed between the first charge generation layer CGL-1 and the second emission layer EML-2, and a second electron transport region ETR-2 disposed between the second emission layer EML-2 and the second electrode EL2.

In the light-emitting device ED-a, the emission layers EML-1 and EML-2 respectively included in the plurality of light-emitting stacks EU-1 and EU-2 may be to emit light in the same wavelength range. For example, each of the emission layers EML-1 and EML-2 included in the plurality of light-emitting stacks EU-1 and EU-2 may be to emit blue light, green light, or red light. However, one or more embodiments of the present disclosure may not be limited thereto, and in the light-emitting device ED-a of one or more embodiments, the emission layers EML-1 and EML-2 included in the plurality of light-emitting stacks EU-1 and EU-2 may be to emit light in different wavelength ranges. For example, the first emission layer EML-1 included in the first light-emitting stack EU-1 may be to emit light of a first wavelength, and the second emission layer EML-2 may be to emit light of a second wavelength that may be different from the first wavelength.

The light-emitting devices ED-a and ED-b according to embodiments may include a charge generation layer CGL-1 disposed between the plurality of light-emitting stacks EU-1 and EU-2. The light-emitting device ED-a of one or more embodiments may include a first charge generation layer CGL-1 disposed between the first light-emitting stack EU-1 and the second light-emitting stack EU-2.

If (e.g., when) a voltage is applied to the light-emitting device ED-a, the charge generation layer CGL-1 may generate charges (electrons and holes) by forming a complex through an oxidation-reduction reaction. In addition, the charge generation layer CGL-1 may provide generated charges to each of adjacent light-emitting stacks EU-1 and EU-2. The charge generation layer CGL-1 may increase the efficiency of current generated from each of the adjacent light-emitting stacks EU-1 and EU-2 and may play a role in controlling the balance of charges between the adjacent light-emitting stacks EU-1 and EU-2.

The charge generation layer CGL-1 may have a layer structure in which an n-type charge generation layer n-CGL and a p-type charge generation layer p-CGL may be joined to each other.

The n-type charge generation layer n-CGL may be a charge generation layer that may provide electrons to adjacent light-emitting stacks EU-1 and EU-2. The n-type charge generation layer n-CGL may be a layer in which an n-dopant may be doped in a base material. The p-type charge generation layer p-CGL may be a charge generation layer that provides holes to adjacent light-emitting stacks EU-1 and EU-2. The p-type charge generation layer p-CGL may be a layer in which a p-dopant may be doped in a base material.

In embodiments, a buffer layer may be further disposed between the n-type charge generation layer n-CGL and the p-type charge generation layer p-CGL.

The charge generation layer CGL-1 may include an n-type aryl amine-based material or a p-type metal oxide. For example, the charge generation layer CGL-1 may include a charge generation compound including an aryl amine-based organic compound, a metal, an oxide, a carbide or a fluoride of a metal, and/or a mixture thereof.

For example, the aryl amine-based organic compound may be α-NPD, 2-TNATA, TDATA, MTDATA, spiro-TAD, and/or spiro-NPB. For example, the metal may be cesium (Cs), molybdenum (Mo), vanadium (V), titanium (Ti), tungsten (W), barium (Ba), and/or lithium (Li). Also, for example, the oxide, carbide, and fluoride of the metal may be Re₂O₇, MoO₃, V₂O₅, WO₃, TiO₂, Cs₂CO₃, BaF, LiF, and/or CsF.

Referring to FIG. 10, a light-emitting device ED-b according to one or more embodiments may include three light-emitting stacks EU-1, EU-2 and EU-3. Compared to the light-emitting device ED-a of one or more embodiments illustrated in FIG. 9, one or more embodiments illustrated in FIG. 10 may be different in including three light-emitting stacks EU-1, EU-2 and EU-3 that may be stacked in the thickness direction.

Referring to FIG. 10, a light-emitting device ED-b according to one or more embodiments of the present disclosure may include three light-emitting stacks EU-1, EU-2 and EU-3 disposed between a first electrode EL1 and a second electrode EL2, and charge generation layers CGL-1 and CGL-2 disposed between the three light-emitting stacks EU-1, EU-2 and EU-3. The charge generation layers CGL-1, and CGL-2 may include a first charge generation layer CGL-1 disposed between the first light-emitting stack EU-1 and the second light-emitting stack EU-2 and a second charge generation layer CGL-2 disposed between the second light-emitting stack EU-2 and the third light-emitting stack EU-3.

Each of the first and second charge generation layers CGL-1 and CGL-2 may include an n-type charge generation layer n-CGL and a p-type charge generation layer p-CGL. Each of the first and second charge generation layers CGL-1 and CGL-2 may have a layer structure in which the n-type charge generation layer n-CGL and the p-type charge generation layer p-CGL are joined to each other.

In the light-emitting device ED-b of one or more embodiments, the plurality of light-emitting stacks EU-1, EU-2 and EU-3 may include emission layers EML-1, EML-2 and EML-3, respectively. Hole transport regions HTR-1, HTR-2 and HTR-3 may be disposed between the first electrode EL1 and the emission layers EML-1, EML-2 and EML3. Electron transport regions ETR-1, ETR-2 and ETR-3 may be disposed between the second electrode EL2 and the emission layer EML-1, EML-2 and EML-3.

In the light-emitting device ED-b of one or more embodiments, the emission layers EML-1, EML-2 and EML-3 respectively included in the plurality of light-emitting stacks EU-1, EU-2 and EU-3 may be to emit light in the same wavelength range. For example, the emission layers EML-1, EML-2 and EML3 included in the plurality of light-emitting stacks EU-1, EU-2 and EU-3 may be to emit blue light, green light, or red light. However, one or more embodiments of the present disclosure may not be limited thereto, and in the light-emitting device ED-b of one or more embodiments, at least two of the emission layers EML-1, EML-2 and EML-3 included in the plurality of light-emitting stacks EU-1, EU-2 and EU-3 may be to emit light in different wavelength ranges. For example, the first emission layer EML-1 included in the first light-emitting stack EU-1 may be to emit light of a first wavelength, the second emission layer EML-2 included in the second light-emitting stack EU-2 may be to emit light of a second wavelength different from the first wavelength, and the third emission layer EML-3 included in the third light-emitting stack EU-3 may be to emit light of a third wavelength different from the first wavelength and the second wavelength. The light-emitting device ED-b including emission layers EML-1, EML-2 and EML3 that generate light of different wavelength ranges may be to emit white light.

The first light-emitting stack EU-1 may include a first emission layer EML-1, a first hole transport region HTR-1 disposed between the first electrode EL1 and the first emission layer EML-1, and a first electron transport region ETR-1 disposed between the first emission layer EML-1 and the first charge generation layer CGL-1. The second light-emitting stack EU-2 may include a second emission layer EML-2, a second hole transport region HTR-2 disposed between the first charge generation layer CGL-1 and the second emission layer EML-2, and a second electron transport region ETR-2 disposed between the second emission layer EML-2 and the second charge generation layer CGL-2. The third light-emitting stack EU-3 may include a third emission layer EML-3, a third hole transport region HTR-3 disposed between the second charge generation layer CGL-2 and the third emission layer EML-3, and a third electron transport region ETR-3 disposed between the third emission layer EML-3 and the second electrode EL2.

In the light-emitting devices ED-a and ED-b according to embodiments, the first electrode EL1 may be a reflective electrode. For example, the first electrode EL1 may include Ag, Mg, Cu, Al, Pt, Pd, Au, Ni, Nd, Ir, Cr, Li, Ca, LiF/Ca, LiF/AI, Mo, Ti, W, In, Zn, Sn, a compound thereof, and/or a mixture thereof (for example, a mixture of Ag and Mg). In embodiments, the first electrode EL1 may have a multilayer structure including a reflective film provided of the above-described material and a transparent conductive film provided of indium tin oxide (e.g., ITO), indium zinc oxide (e.g., IZO), zinc oxide (e.g., ZnO), indium tin zinc oxide (ITZO), and/or the like. For example, the first electrode EL1 may have a two-layer structure of ITO/Ag and a three-layer structure of ITO/Ag/ITO, but one or more embodiments of the present disclosure is not limited thereto. In addition, one or more embodiments of the present disclosure is not limited thereto, and the first electrode EL1 may include the above-described metal material, a combination of two or more metal materials selected from among the above-described metal materials, or an oxide of the above-described metal materials. The thickness of the first electrode EL1 may be about 70 nm to about 1000 nm. For example, the thickness of the first electrode EL1 may be about 100 nm to about 300 nm.

In the light-emitting devices ED-a and ED-b according to embodiments, the second electrode EL2 may be disposed on the uppermost light-emitting stack among the plurality of light-emitting stacks. For example, if (e.g., when) the light-emitting device ED may have the structure illustrated in FIG. 9, the second electrode EL2 may be disposed on the second light-emitting stack EU-2. The second electrode EL2 may be directly disposed on the second electron transport region ETR-2 included in the second light-emitting stack EU-2. A bottom surface of the second electrode EL2 may be in contact with the second electron transport region ETR-2. In embodiments, if (e.g., when) the light-emitting element ED may have the structure illustrated in FIG. 10, the second electrode EL2 may be disposed on the third light-emitting stack EU-3. The second electrode EL2 may be directly disposed on the third electron transport region ETR-3 included in the third light-emitting stack EU-3. The bottom surface of the second electrode EL2 may be in contact with the third electron transport region ETR-3.

The second electrode EL2 may be a common electrode. The second electrode EL2 may be a cathode or an anode, but one or more embodiments of the present disclosure is not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may include a silver (Ag)-palladium (Pd)-copper (Cu) alloy. The second electrode EL2 may include a silver (Ag)-palladium (Pd)-copper (Cu) alloy in which the silver (Ag) content (e.g., amount) may be higher than the palladium (Pd) and copper (Cu) contents. The silver (Ag)-palladium (Pd)-copper (Cu) alloy may be a silver-rich (Ag-rich) alloy in which the silver (Ag) content may be higher than the palladium (Pd) and copper (Cu) contents, respectively. In one or more embodiments, the second electrode EL2 may include (e.g., be composed of) a silver (Ag)-palladium (Pd)-copper (Cu) alloy.

Silver (Ag) may be a metal having high electrical conductivity and low light absorption and may improve electrical and optical characteristics. Silver (Ag) may be included in an amount of about 97.9 wt % or more and about 99.9 wt % or less based on the total 100 wt % of a total weight of the silver (Ag)-palladium (Pd)-copper (Cu) alloy. If (e.g., when) the silver (Ag) content is less than about 97.9 wt %, the sheet resistance of the electrode may increase, which may deteriorate the electrical characteristics. In addition, if (e.g., when) the silver (Ag) content exceeds about 99.9 wt %, the stability of an electrode thin film may be deteriorated due to the agglomeration of silver (Ag). By including the silver (Ag) of the second electrode EL2 within the above range, the stability of the electrode thin film may be secured while exhibiting excellent electrical and optical characteristics.

Palladium (Pd) and copper (Cu) may improve the stability of the thin film by suppressing the agglomeration of silver (Ag) included in the second electrode EL2 and play a role in lowering the sheet resistance of the second electrode EL2. Silver (Ag) is a material with a strong agglomeration property, and if (e.g., when) utilized as a single material to form an electrode thin film, agglomeration between elements may occur during deposition, which may form islands on the surface of the electrode thin film. If (e.g., when) an island may be provided on the surface of the electrode thin film, the stability of the thin film may be deteriorated, and the sheet resistance may increase, which may deteriorate the electrical characteristics of the electrode. In the present disclosure, the second electrode may exhibit excellent film stability by including palladium (Pd) and copper (Cu) together with silver (Ag) and may improve electrical characteristics by having low sheet resistance.

Palladium (Pd) may be included in an amount of about 0.01 wt % or more and less than about 0.1 wt % based on 100 wt % of the total weight of the total silver (Ag)-palladium (Pd)-copper (Cu) alloy. If (e.g., when) the palladium (Pd) content is less than about 0.01 wt %, the silver (Ag) agglomeration prevention/reduction effect may be reduced, and the film stability may be reduced. In addition, if (e.g., when) the palladium (Pd) content is about 0.1 wt % or more, the adhesion with an underlying substrate is reduced, and the electrical characteristics of the silver film may be reduced. Because the second electrode EL2 may include palladium (Pd) in the above range, the stability of the electrode film may be secured while improving efficiency.

Copper (Cu) may be included in an amount of about 0.01 wt % or more and about 2.0 wt % or less based on 100 wt % of the total weight of the total silver (Ag)-palladium (Pd)-copper (Cu) alloy. If (e.g., when) the copper (Cu) content is less than about 0.01 wt %, the silver (Ag) agglomeration prevention/reduction effect may be reduced, thereby deteriorating the stability of the thin film. In addition, if (e.g., when) the copper (Cu) content exceeds about 2.0 wt %, the adhesion with an underlying substrate may be reduced, and the electrical characteristics of the silver thin film may be deteriorated. Because the second electrode EL2 may include copper (Cu) within the above range, the stability of the electrode thin film may be secured while improving the efficiency.

In one or more embodiments, the palladium (Pd) content in the second electrode EL2 may be smaller than the copper (Cu) content. Table 1 below shows the resistivity of silver (Ag), palladium (Pd), and copper (Cu). Referring to Table 1 below, copper (Cu) may have a lower resistivity than palladium (Pd). By making the content of copper (Cu), which may have a low resistivity, larger than the content of palladium (Pd), the stability of the thin film of the second electrode EL2 may be ensured while further improving the electrical characteristics.

TABLE 1

| Physical properties | Ag | Pd | Cu |
|---|---|---|---|
| Resistivity [m · Ω] | 1.6 × 10\hat{ }−8 | 1 × 10\hat{ }−7 | 1.7 × 10\hat{ }−8 |

In one or more embodiments, the second electrode EL2 may further include nickel (Ni). For example, the second electrode EL2 may include a silver (Ag)-palladium (Pd)-copper (Cu)-nickel (Ni) alloy. The second electrode EL2 may include a silver (Ag)-palladium (Pd)-copper (Cu)-nickel (Ni) alloy having the silver (Ag) content higher than the contents of palladium (Pd), copper (Cu), and nickel (Ni), respectively. The silver (Ag)-palladium (Pd)-copper (Cu)-nickel (Ni) alloy may be a silver-rich (Ag-rich) alloy having the silver (Ag) content higher than the contents of palladium (Pd), copper (Cu), and nickel (Ni), respectively. In one or more embodiments, the second electrode EL2 may be composed of a silver (Ag)-palladium (Pd)-copper (Cu)-nickel (Ni) alloy.

Nickel (Ni) may be included in the electrode thin film containing silver (Ag) to contribute to improving electrical conductivity, and/or the like. In addition, nickel (Ni) may have a function of preventing or reducing agglomeration of silver (Ag) like palladium (Pd), and copper (Cu), thereby improving the stability and electrical characteristics of the thin film. The second electrode EL2 containing nickel (Ni) may further improve the electrical characteristics and the stability characteristics of the thin film, thereby improving the electrical reliability.

If (e.g., when) the second electrode EL2 may further include nickel, nickel (Ni) may be included in an amount of about 0.01 wt % or more and about 2.0 wt % or less based on 100 wt % of the total weight of the total silver (Ag)-palladium (Pd)-copper (Cu)-nickel (Ni) alloy. As the second electrode EL2 may include nickel (Ni) within the above range, excellent electrical characteristics and excellent film stability may be exhibited.

Silver (Ag) may be included in an amount of about 97.9 wt % or more and about 99.9 wt % or less based on 100 wt % of the total weight of the total silver (Ag)-palladium (Pd)-copper (Cu)-nickel (Ni) alloy. As silver (Ag) is included within the above range, excellent electrical characteristics and optical characteristics may be exhibited, while ensuring the stability of the electrode film.

Palladium (Pd) may be included in an amount of about 0.01 wt % or more and less than about 0.1 wt % based on 100 wt % of the total weight of the total silver (Ag)-palladium (Pd)-copper (Cu)-nickel (Ni) alloy. Based on the total weight (e.g., 100 wt %) of the silver (Ag)-palladium (Pd)-copper (Cu)-nickel (Ni) alloy, copper (Cu) may be included in an amount of about 0.01 wt % or more and about 2.0 wt % or less. By including palladium (Pd) and copper (Cu) within the above ranges, the stability of the electrode thin film may be secured while improving the efficiency.

The thickness of the second electrode EL2 may be about 30 Å or more and about 150 Å or less. If (e.g., when) the thickness of the second electrode EL2 is less than about 30 Å, sufficient film quality may not be secured if (e.g., when) forming the second electrode EL2 film utilizing the silver (Ag)-palladium (Pd)-copper (Cu) alloy, and thus the function of the second electrode EL2 may be reduced. If (e.g., when) the thickness of the second electrode EL2 exceeds about 150 Å, the resonance structure within the light-emitting device may be changed, making it difficult to satisfy optical characteristics such as optical efficiency characteristics and viewing angle characteristics. By controlling the thickness of the second electrode EL2 within the above-described range, the suitable optical characteristics may be stably maintained while exhibiting low sheet resistance, thereby preventing or reducing a voltage drop phenomenon occurring at a common electrode.

In one or more embodiments, the sheet resistance of the second electrode EL2 may be about 0.1Ω/□ or more and about 10Ω/□ or less.

In the light-emitting devices ED-a and ED-b of embodiments, the second electrode may include a silver (Ag) palladium (Pd)-copper (Cu) alloy, and silver (Ag), palladium (Pd), and copper (Cu) are included in corresponding ranges within the alloy. Accordingly, the sheet resistance of the second electrode, which is the common electrode, is reduced, so that a voltage drop (IR drop) phenomenon occurring at the second electrode may be prevented or reduced, and power consumption may be reduced.

A tandem device structure including a plurality of light-emitting stacks may include two or more emission layers, so that the driving voltage increases compared to a general light-emitting device including a single light-emitting stack, which may increase power consumption. In order to improve the power consumption of the tandem device, a method of reducing the sheet resistance of the common electrode may be utilized. In the conventional light-emitting devices, the common electrode is utilized in the form of a silver (Ag)-magnesium (Mg) alloy, but because the sheet resistance is about 150/□ at a thickness of about 95 Å, if (e.g., when) applied to a tandem device structure, a voltage drop (IR drop) may occur, which may cause uneven luminance or increased power consumption. In order to reduce the sheet resistance, a method of increasing the thickness of the silver (Ag)-magnesium (Mg) common electrode may be utilized, but if (e.g., when) the thickness increases beyond a corresponding level, a resonance structure within the tandem device changes, which causes problems in that the suitable light efficiency and viewing angle characteristics are deteriorated.

In the present disclosure, the second electrode, which may be a common electrode, may include (e.g., may be formed of) a silver (Ag)-palladium (Pd)-copper (Cu) alloy, and by controlling the contents of silver (Ag), palladium (Pd), and/or copper (Cu) in the alloy to corresponding ranges, the sheet resistance of the second electrode may be effectively reduced without significantly increasing the thickness. Accordingly, the voltage drop phenomenon occurring in the common electrode may be reduced while stably maintaining the suitable optical characteristics, and the power consumption may be reduced by reducing the driving voltage.

In embodiments, the second electrode EL2 may be connected to an auxiliary electrode. If (e.g., when) the second electrode EL2 is connected to the auxiliary electrode, the resistance of the second electrode EL2 may be reduced.

A capping layer CPL may be further disposed on the second electrode EL2 of the light-emitting devices ED-a and ED-b of embodiments. The capping layer CPL may include a multilayer or a single layer.

In one or more embodiments, the capping layer CPL may be an organic layer or an inorganic layer. For example, if (e.g., when) the capping layer CPL may include an inorganic material, the inorganic material may include an alkali metal compound such as LiF, an alkaline earth metal compound such as MgF₂, SiON, SiNₓ, SiO_{y}, and/or the like.

For example, if (e.g., when) the capping layer CPL may include an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris (carbazol sol-9-yl) triphenylamine (TCTA), and/or the like, or may include an epoxy resin or an acrylate such as a methacrylate. However, one or more embodiments of the present disclosure may not be limited thereto, and the capping layer CPL may include at least one of the compounds P1 to P5 below.

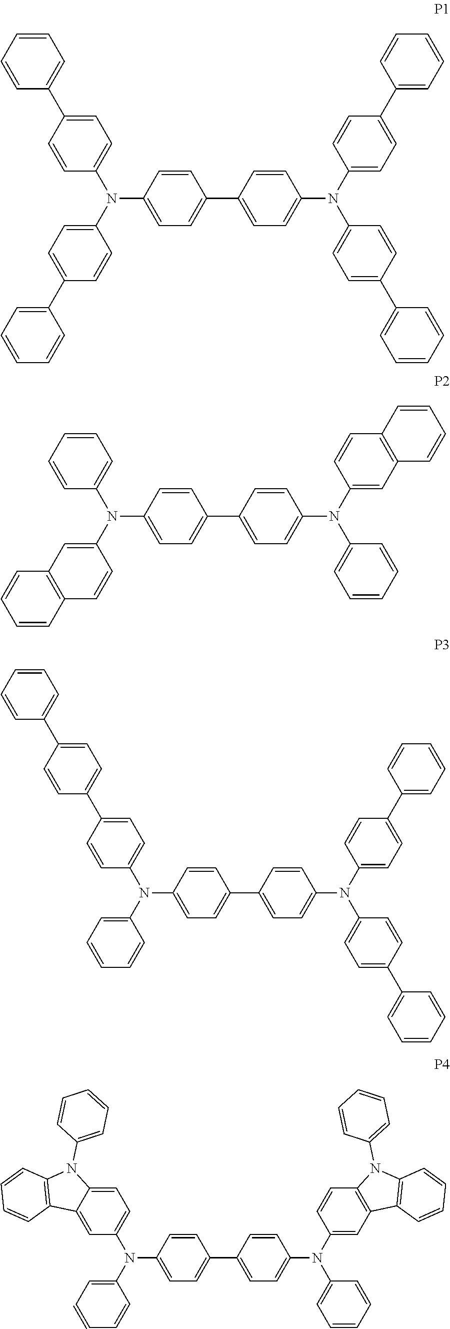 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

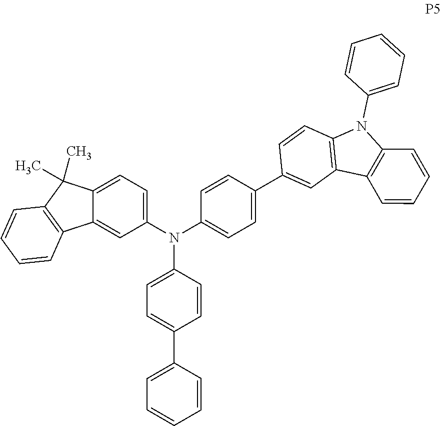 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. For example, the refractive index of the capping layer CPL may be about 1.6 or more for light in a wavelength range of about 550 nm or more and about 660 nm or less.

In the light-emitting devices ED-a and ED-b of embodiments, the plurality of light-emitting stacks EU-1, EU-2 and EU-3 may include emission layers EML-1, EML-2 and EML-3, respectively. Each of the plurality of light-emitting stacks EU-1, EU-2 and EU-3 may include stacked hole transport regions HTR-1, HTR-2 and HTR-3, emission layers EML-1, EML-2 and EML-3, and electron transport regions ETR-1, ETR-2 and ETR-3. For example, the light-emitting devices ED-a and ED-b of embodiments may be light-emitting devices having a tandem structure including a plurality of emission layers stacked in the thickness direction.

The hole transport regions HTR-1, HTR-2 and HTR-3 included in the plurality of light-emitting stacks EU-1, EU-2 and EU-3 may have a single layer including (e.g., formed of) a single material, a single layer including a plurality of different materials, and/or a multilayer structure having a plurality of layers including a plurality of different materials.

Each of the hole transport regions HTR-1, HTR-2 and HTR-3 may be provided utilizing suitable methods such as a vacuum deposition method, a spin coating method, a casting method, a Langmuir-Blodgett (LB) method, an inkjet printing method, a laser printing method, a laser induced thermal imaging (LITI), and/or the like.

Each of the hole transport regions HTR-1, HTR-2 and HTR-3 may include a known hole transport material. For example, the hole transport regions HTR-1, HTR-2 and HTR-3 may further include a phthalocyanine compound such as copper phthalocyanine, N1,N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N-(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-I-yl)-N,N′-diphenyl-benzidine (NPB (or NPD, α-NPD)), polyether ketone containing triphenylamine (TPAPEK), 4-isopropyl-4′-methyldiphenyliodonium [tetrakis(pentafluorophenyl)borate], dipyrazino[2,3-f: [2′,3′-h]quinoxaline-2,3,6,7,10,11-hexacarbonitrile (HATCN), and/or the like.

The hole transport regions HTR-1, HTR-2 and HTR-3 may include carbazole derivatives such as N-phenylcarbazole and polyvinylcarbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalene-I-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In addition, the hole transport regions HTR-1, HTR-2 and HTR-3 may include 9-(4-tert-butylphenyl)-3,6-bis(triphenylsilyl)-9H-carbazole (CzSi), 9-phenyl-9H-3,9′-bicarbazole (CCP), or 1,3-bis(1,8-dimethyl-9H-carbazol-9-yl)benzene (mDCP), and/or the like.

In addition to the above-described materials, the hole transport regions HTR-1, HTR-2 and HTR-3 may further include a charge generating material to improve conductivity. The charge generating material may be uniformly or non-uniformly dispersed within the hole transport regions HTR-1, HTR-2 and HTR-3. The charge generating material may be, for example, a p-dopant. The p-dopant may include at least one of a halogenated metal compound, a quinone derivative, a metal oxide, or a cyano group-containing compound, but one or more embodiments of the present disclosure may not be limited thereto. For example, the p-dopant may include a halogenated metal compound such as CuI and RbI, a quinone derivative such as tetracyanoquinodimethane (TCNQ) and 2,3,5,6-tetrafluoro-7,7,8,8-tetracyanoquinodimethane (F4-TCNQ), a metal oxide such as tungsten oxide and molybdenum oxide, dipyrazino[2,3-f: 2′,3′-h]quinoxaline-2,3,6,7,10,11-hexacarbonitrile (HATCN) and a cyano group-containing compound such as 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), but one or more embodiments of the present disclosure may not be limited thereto.

Each of the hole transport regions HTR-1, HTR-2 and HTR-3 may include a hole injection layer and a hole transport layer. In addition, the hole transport regions HTR-1, HTR-2 and HTR-3 may include at least one of a hole injection layer, a hole transport layer, a buffer layer or a light-emitting auxiliary layer, and an electron blocking layer. In one or more embodiments, the hole transport regions HTR-1, HTR-2 and HTR-3 have a single layer structure including a plurality of different materials, or a sequentially stacked structure of hole injection layer/hole transport layer, hole injection layer/hole transport layer/buffer layer, hole injection layer/buffer layer, or a hole transport layer/buffer layer, but one or more embodiments of the present disclosure may not be limited thereto. The material of a hole transport region may be included in at least one of a hole injection layer, a hole transport layer, a buffer layer or a light-emitting auxiliary layer, or an electron blocking layer.

In the light-emitting devices ED-a and ED-b of embodiments, the electron transport regions ETR-1, ETR-2 and ETR-3 included in the plurality of light-emitting stacks EU-1, EU-2 and EU-3 may have a multilayer structure having a single layer including a single material, a single layer including a plurality of different materials, or a multilayer structure having a plurality of layers including a plurality of different materials.

Each of the electron transport regions ETR-1, ETR-2 and ETR-3 may be provided utilizing suitable methods such as a vacuum deposition method, a spin coating method, a casting method, a Langmuir-Blodgett (LB) method, an inkjet printing method, a laser printing method, and a laser induced thermal imaging (LITI) method.

The electron transport regions ETR-1, ETR-2 and ETR-3 may include an anthracene compound. However, one or more embodiments of the present disclosure may not be limited thereto, and the electron transport regions ETR-1, ETR-2 and ETR-3 may include, for example, tris(8-hydroxyquinolinato)aluminum (Alq₃), 1,3,5-tri[(3-pyridyl)-phen-3-yl]benzene, 2,4,6-tris(biphenyl-3-yl)-1,3,5-triazine (T2T), 2,4,6-tris(3-(pyrimidin-5-yl)phenyl)-1,3,5-triazine (TPM-TAZ), 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), and/or mixtures thereof.

In addition, the electron transport regions ETR-1, ETR-2 and ETR-3 may include a halogenated metal such as LiF, NaCl, CsF, RbCl, RbI, CuI and KI, a lanthanide metal such as Yb, and a co-deposition material of the halogenated metal and the lanthanide metal. For example, the electron transport regions ETR-1, ETR-2 and ETR-3 may include KI:Yb, RbI:Yb, LiF:Yb, and/or the like, as the co-deposition material. The electron transport regions ETR-1, ETR-2 and ETR-3 may utilize a metal oxide such as Li₂O and BaO, or 8-hydroxyl-lithium quinolate (Liq), but one or more embodiments of the present disclosure may not be limited thereto. The electron transport regions ETR-1, ETR-2 and ETR-3 may also include a material in which an electron transport material and an insulating organo metal salt are mixed. The organo metal salt may be a material having an energy band gap of approximately 4 eV or more. For example, the organo metal salt may include metal acetate, metal benzoate, metal acetoacetate, metal acetylacetonate, or metal stearate.

The electron transport regions ETR-1, ETR-2 and ETR-3 may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials mentioned above, but one or more embodiments of the present disclosure may not be limited thereto.

Each of the electron transport regions ETR-1, ETR-2 and ETR-3 may include an electron transport layer and an electron injection layer. In addition, each of the electron transport regions ETR-1, ETR-2 and ETR-3 may include at least one of an electron injection layer, an electron transport layer, or a hole blocking layer. In one or more embodiments, the electron transport regions ETR-1, ETR-2 and ETR-3 may have a stacked structure of electron transport layer/electron injection layer, hole blocking layer/electron transport layer/electron injection layer, electron transport layer/buffer layer/electron injection layer, and/or the like, but one or more embodiments of the present disclosure may not be limited thereto. At least one of the electron injection layer, the electron transport layer, or the hole blocking layer may include a material of the electron transport region described above.

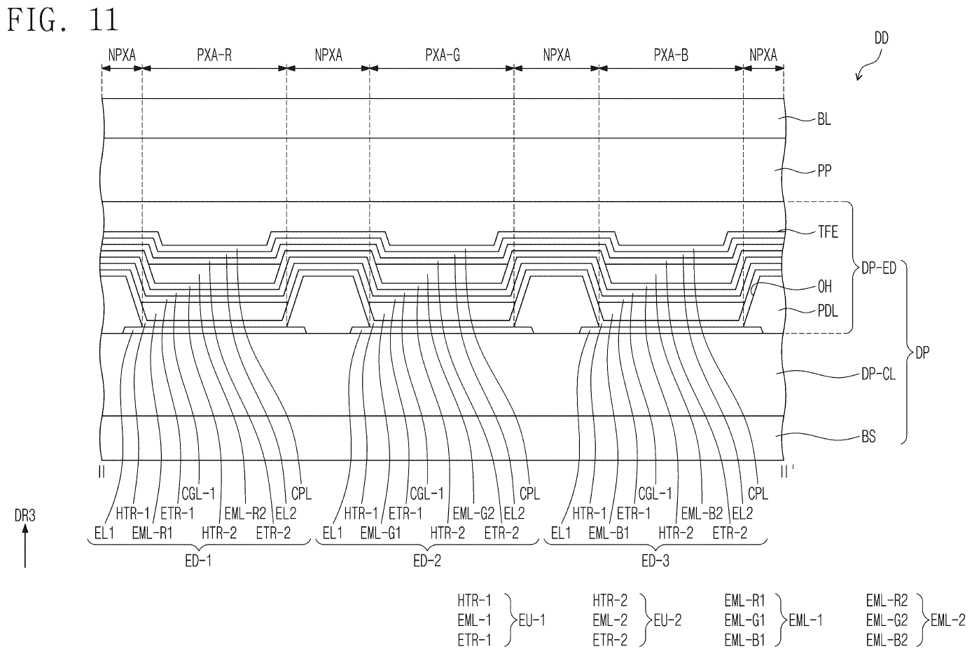

FIG. 11 is a cross-sectional view of a display device DD according to one or more embodiments of the present disclosure. FIG. 11 is a cross-sectional view showing a portion corresponding to line II-II′ in FIG. 7. In FIG. 11, some components of the display device DD, such as the input sensor IS, the adhesive layer PSA and the window WM in FIG. 5 may be not omitted.

The display device DD according to one or more embodiments may include a display panel DP and an optical layer PP disposed on the display panel DP. The display panel DP may include light-emitting devices ED-1, ED-2 and ED-3. The display device DD may include a plurality of light-emitting devices ED-1, ED-2 and ED-3.

The optical layer PP may be disposed on the display panel DP to control reflected light from the display panel DP due to external light. The optical layer PP may include, for example, a polarizing layer or a color filter layer. The optical layer PP may not be repeated in the display device DD.

A base substrate BL may be disposed on the optical layer PP. The base substrate BL may be a substrate that may provide a base surface on which the optical layer PP may be disposed. The base substrate BL may be a glass substrate, a metal substrate, a plastic substrate, and/or the like. However, one or more embodiment of the present disclosure may not be limited thereto, and the base substrate BL may be an inorganic layer, an organic layer, or a composite material layer. In addition, the base substrate BL may not be repeated here.

The display device DD according to one or more embodiments may further include a filling layer. The filling layer may be disposed between the display device layer DP-ED and the base substrate BL. The filling layer may be an organic layer. The filling layer may include at least one of an acrylic resin, a silicone-based resin, and an epoxy-based resin.

The display panel DP may include a base layer BS, a circuit layer DP-CL provided on the base layer BS, and a display device layer DP-ED. The display device layer DP-ED may include a pixel defining layer PDL, light-emitting devices ED-1, ED-2 and ED-3 disposed in the pixel defining layer PDL, and an encapsulation layer TFE disposed on the light-emitting devices ED-1, ED-2 and ED-3.

The base layer BS may be a layer that may provide a base surface on which the display device layer DP-ED may be disposed. The base layer BS may be a glass substrate, a metal substrate, a plastic substrate, and/or the like. However, one or more embodiments of the present disclosure may not be limited thereto, and the base layer BS may be an inorganic layer, an organic layer, and/or a composite material layer.

In one or more embodiments, the circuit layer DP-CL may be disposed on the base layer BS, and the circuit layer DP-CL may include a plurality of transistors. The transistors may include a control electrode, an input electrode, and an output electrode, respectively. For example, the circuit layer DP-CL may include a switching transistor and a driving transistor for driving the light-emitting devices ED-1, ED-2 and ED-3 of the display device layer DP-ED.

Each of the light-emitting devices ED-1, ED-2 and ED-3 may include two or more light-emitting stacks EU-1, EU-2 and ED-3 (see FIGS. 9 and 10) that are stacked in the thickness direction. Each of the light-emitting devices ED-1, ED-2 and ED-3 may have a structure of the light-emitting device ED according to FIGS. 9 and 10 described above. Each of the two or more light-emitting stacks EU-1, EU-2 and ED-3 (see FIGS. 9 and 10) may include an emission layer.

In FIG. 11, light-emitting devices ED-1, ED-2 and ED-3 having the structure of FIG. 9 are illustrated. Referring to FIG. 9 and FIG. 11, the first to third light-emitting devices ED-1, ED-2 and ED-3 may include a first electrode EL1, a second electrode EL2 facing the first electrode EL1, and a plurality of light-emitting stacks EU-1 and EU-2 between the first electrode EL1 and the second electrode EL2. In addition, the light-emitting devices ED-1, ED-2 and ED-3 may include a charge generation layer CGL-1 disposed between the light-emitting stacks EU-1 and EU-2.

In each of the first to third light-emitting devices ED-1, ED-2 and ED-3, emission layers included in two or more light-emitting stacks may be to emit light in the same wavelength range. For example, the light-emitting stacks included in the first light-emitting device ED-1 may include red emission layers EML-R1 and EML-R2, the light-emitting stacks included in the second light-emitting device ED-2 may include green emission layers EML-G1 and EML-G2, and the light-emitting stacks included in the third light-emitting device ED-3 may include blue emission layers EML-B1 and EML-B2.

The first light-emitting stack EU-1 included in the first light-emitting device ED-1 may include a first hole transport region HTR-1, a first red emission layer EML-R1, and a first electron transport region ETR-1, sequentially stacked on the first electrode EL1. In addition, the second light-emitting stack EU-2 included in the first light-emitting device ED-1 may include a second hole transport region HTR-2, a second red emission layer EML-R2, and a second electron transport region ETR-2, sequentially stacked on the first charge generation layer CGL-1.

The first light-emitting stack EU-1 included in the second light-emitting device ED-2 may include a first hole transport region HTR-1, a first green emission layer EML-G1, and a first electron transport region ETR-1, sequentially stacked on the first electrode EL1. In addition, the second light-emitting stack EU-2 included in the second light-emitting device ED-2 may include a second hole transport region HTR-2, a second green emission layer EML-G2, and a second electron transport region ETR-2, sequentially stacked on the first charge generation layer CGL-1.

The first light-emitting stack EU-1 included in the third light-emitting device ED-3 may include a first hole transport region HTR-1, a first blue emission layer EML-B1, and a first electron transport region ETR-1, sequentially stacked on the first electrode EL1. In addition, the second light-emitting stack EU-2 included in the third light-emitting device ED-3 may include a second hole transport region HTR-2, a second blue emission layer EML-B2, and a second electron transport region ETR-2, sequentially stacked on the first charge generation layer CGL-1.

The first to third light-emitting devices ED-1, ED-2 and ED-3 may further include a capping layer CPL disposed on the second electrode EL2.

The hole transport regions HTR-1 and HTR-2, the charge generation layer CGL-1, and the electron transport region ETR-1 and ETR-2, included in the first to third light-emitting devices ED-1, ED-2 and ED-3 may be provided as common layers throughout the first to third light-emitting devices ED-1, ED-2 and ED-3. However, one or more embodiments of the present disclosure may not be limited thereto, and the hole transport regions HTR-1 and HTR-2, the charge generation layer CGL-1, and the electron transport regions ETR-1 and ETR-2 may be provided by being patterned within an opening part OH defined in a pixel defining layer PDL.

An encapsulation layer TFE may cover the light-emitting devices ED-1, ED-2 and ED-3. The encapsulation layer TFE may seal the display device layer DP-ED. The encapsulation layer TFE may be a thin film encapsulation layer. The encapsulation layer TFE may be a single layer or a plurality of layers stacked. The encapsulation layer TFE may include at least one insulating layer. The encapsulation layer TFE may include a first encapsulation inorganic layer 141 (see FIG. 8), an encapsulation organic layer 142 (see FIG. 8), and a second encapsulation inorganic layer 143 (see FIG. 8) described above. The first encapsulation inorganic layer 141 (see FIG. 8) may be directly disposed on the capping layer CPL of each of the light-emitting devices ED-1, ED-2 and ED-3.

The encapsulation layer TFE may be disposed on the second electrode EL2 and may be disposed to fill the opening part OH.

Referring to FIGS. 7 and 11, the display device DD may include a non-light-emitting area NPXA and light-emitting areas PXA-R, PXA-G and PXA-B. Each of the light-emitting areas PXA-R, PXA-G and PXA-B may be an area in which light generated from each of the light-emitting devices ED-1, ED-2 and ED-3 is emitted. The light-emitting areas PXA-R, PXA-G and PXA-B may be spaced and/or apart (e.g., spaced apart or separated) from each other on a plane.

Each of the light-emitting areas PXA-R, PXA-G and PXA-B may be an area separated by a pixel defining layer PDL. The non-light-emitting area NPXA may be an area between neighboring light-emitting areas PXA-R, PXA-G and PXA-B and may be an area corresponding to the pixel defining layer PDL. In the present disclosure, each of the light-emitting areas PXA-R, PXA-G and PXA-B may correspond to a pixel. The pixel defining layer PDL may distinguish the light-emitting devices ED-1, ED-2 and ED-3. The emission layers EML-R1, EML-R2, EML-G1, EML-G2, EML-B1 and EML-B2 of the light-emitting devices ED-1, ED-2 and ED-3 may be disposed in opening parts OH defined in the pixel defining layer PDL and distinguished.

The light-emitting areas PXA-R, PXA-G, and PXA-B may be classified into a plurality of groups according to the color of light generated from the light-emitting devices ED-1, ED-2 and ED-3. The display device DD according to one or more embodiments illustrated in FIGS. 7 and 11 illustrates three light-emitting areas PXA-R, PXA-G and PXA-B that emit red light, green light and blue light. For example, the display device DD according to one or more embodiments may include a red light-emitting area PXA-R, a green light-emitting area PXA-G and a blue light-emitting area PXA-B that are distinct from each other.

In the display device DD according to one or more embodiment, the plurality of light-emitting devices ED-1, ED-2 and ED-3 may be to emit light of different wavelength regions. For example, the display device DD may include a first light-emitting device ED-1 that may be to emit red light, a second light-emitting device ED-2 that may be to emit green light, and a third light-emitting device ED-3 that may be to emit blue light. For example, the red light-emitting area PXA-R, the green light-emitting area PXA-G, and the blue light-emitting area PXA-B of the display device DD may correspond to the first light-emitting device ED-1, the second light-emitting device ED-2, and the third light-emitting device ED-3, respectively.

However, one or more embodiment of the present disclosure may not be limited thereto, and the first to third light-emitting devices ED-1, ED-2 and ED-3 may be to emit light of the same wavelength range, or at least one may be to emit light of a different wavelength range. For example, the first to third light-emitting devices ED-1, ED-2 and ED-3 may all emit blue light.

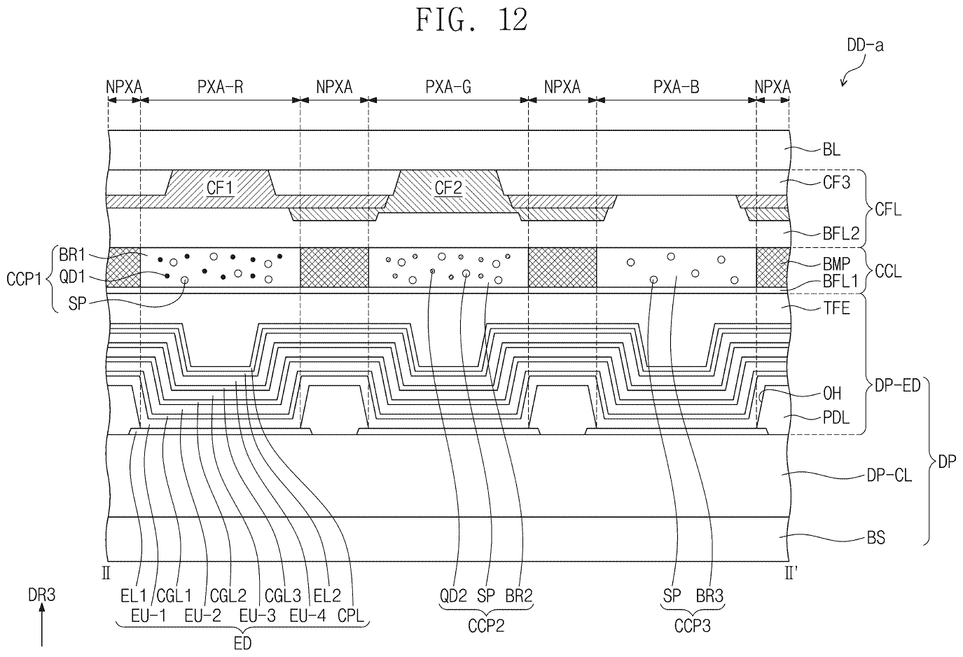

FIG. 12 is a cross-sectional view of a display device according to one or more embodiment of the present disclosure. In the description of the display device according to one or more embodiments below with reference to FIG. 12, any content overlapping with that described in FIGS. 1 to 11 described above will not be described again, and differences will be mainly described.

Referring to FIG. 12, a display device DD-a according to one or more embodiments may include a display panel DP including a display device layer DP-ED, a light control layer CCL disposed on the display panel DP, and a color filter layer CFL. In one or more embodiments, in FIG. 12, the display panel DP may include a base layer BS, a circuit layer DP-CL provided on the base layer BS, and a display device layer DP-ED, and the display device layer DP-ED may include a light-emitting device ED.

Each of the light-emitting devices ED-1, ED-2 and ED-3 may include two or more light-emitting stacks EU-1, EU-2 and ED-3 (see FIGS. 9 and 10) that are stacked in the thickness direction. The light-emitting device ED may have the structure of the light-emitting device ED according to one or more embodiment of FIGS. 9 and 10 described above. Each of two or more light-emitting stacks EU-1, EU-2 and ED-3 (see FIGS. 9 and 10) may include an emission layer. FIG. 12 illustrates one or more embodiments of a light-emitting device ED including four light-emitting stacks EU-1, EU-2, EU-3 and EU-4.

The light-emitting device ED may include first to fourth light-emitting stacks EU-1, EU-2, EU-3 and EU-4 that face each other and are sequentially stacked in the thickness direction between the first electrode EL1 and the second electrode EL2.

Charge generation layers CGL1, CGL2 and CGL3 may be disposed between the first to fourth light-emitting stacks EU-1, EU-2, EU-3 and EU-4. The charge generation layers CGL1, CGL2 and CGL3 disposed between the neighboring light-emitting stacks EU-1, EU-2, EU-3 and EU-4 may include a p-type charge generation layer and/or an n-type charge generation layer.

The light emitted from each of the light-emitting stacks EU-1, EU-2, EU-3 and EU-4 may all be blue light. In embodiments, at least two of the light-emitting stacks EU-1, EU-2, EU-3 and EU-4 may be to emit light in different wavelength ranges. For example, among the four light-emitting stacks illustrated in FIG. 12, the first to third light-emitting stacks EU-1, EU-2 and EU-3 may be to emit blue light, and the fourth light-emitting stack EU-4 may be to emit green light.

Each of the light-emitting stacks EU-1, EU-2, EU-3 and EU-4 included in the display device DD-a may include an emission layer and a charge control layer. Each of the light-emitting stacks EU-1, EU-2, EU-3 and EU-4 may include a hole transport region, an emission layer, and an electron transport region. For example, a first light-emitting stack EU-1 may include a first hole transport region, a first emission layer, and a first electron transport region, which are sequentially stacked in the thickness direction. A second light-emitting stack EU-2 may include a second hole transport region, a second emission layer, and a second electron transport region, which are sequentially stacked in the thickness direction. A third light-emitting stack EU-3 may include a third hole transport region, a third emission layer, and a third electron transport region, which are sequentially stacked in the thickness direction. A fourth light-emitting stack EU-4 may include a fourth hole transport region, a fourth emission layer, and a fourth electron transport region, which are sequentially stacked in the thickness direction.

The light control layer CCL may be disposed on the display panel DP. The light control layer CCL may include a light converter. The light converter may be a quantum dot or a phosphor. The light converter may convert the wavelength of the light provided and emit the converted light. For example, the light control layer CCL may be a layer including a quantum dot or a layer including a phosphor.

The light control layer CCL may include a plurality of light control parts CCP1, CCP2 and CCP3. The light control parts CCP1, CCP2 and CCP3 may be spaced and/or apart (e.g., spaced apart or separated) from each other.

Referring to FIG. 12, a partition pattern BMP may be disposed between the light control parts CCP1, CCP2 and CCP3 that are spaced and/or apart (e.g., spaced apart or separated) from each other, but one or more embodiment of the present disclosure may not be limited thereto. In FIG. 12, the partition pattern BMP is depicted as not overlapping with the light control parts CCP1, CCP2 and CCP3, but the edges of the light control parts CCP1, CCP2 and CCP3 may overlap at least partly with the partition pattern BMP.

At least a portion of the light control parts CCP1, CCP2 and CCP3 may include quantum dots.

In the present disclosure, a quantum dot may refer to a crystal of a semiconductor compound. The quantum dot may be to emit light of suitable emission wavelengths depending on the size of the crystal. The quantum dot may also emit light of suitable emission wavelengths by controlling the element ratio in the quantum dot compound.

The diameter of the quantum dot may be, for example, about 1 nm to 10 nm.

The quantum dot may be synthesized by a wet chemical process, a metal organic chemical vapor deposition process, a molecular beam epitaxy process, or a similar process.

The wet chemical process is a method of growing a quantum dot particle crystal after mixing an organic solvent and a precursor material. If (e.g., when) the crystal grows, the organic solvent naturally acts as a dispersant coordinated on the surface of the quantum dot crystal and may control the growth of the crystal. Therefore, the wet chemical processes may control the growth of quantum dot particles through easier and less costly processes than vapor deposition methods such as metal organic chemical vapor deposition (MOCVD) or molecular beam epitaxy (MBE).

The emission layer EML of the present disclosure may include a quantum dot material. The core of the quantum dot may be selected from among a II-VI group compound, a III-V group compound, a III-VI group compound, a I-III-VI group compound, a IV-VI group compound, a IV group element, a IV group compound, and/or combinations thereof.

The II-VI group compound may be selected from among the group including: a binary compound selected from among the group including CdSe, CdTe, CdS, ZnS, ZnSe, ZnTe, ZnO, HgS, HgSe, HgTe, MgSe, MgS, and/or mixtures thereof; a ternary compound selected from among the group including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or mixtures thereof; and a quaternary compound selected from among the group including HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The II-VI group semiconductor compound may further include a I group metal and/or a IV group element. The I-II-VI group compound may be selected from among CuSnS or CuZnS, and the II-IV-VI group compound may be selected from among ZnSnS, and/or the like. The I-II-IV-VI group compound may be selected from among a quaternary compound selected from among the group including Cu₂ZnSnS₂, Cu₂ZnSnS₄, Cu₂ZnSnSe₄, Ag₂ZnSnS₂, and/or mixtures thereof.

The III-VI group compound may include a binary compound such as In₂S₃, and In₂Se₃, a ternary compound such as InGaS₃, and InGaSe₃, and/or arbitrary combinations thereof.

The I-III-VI group compound may be selected from among a ternary compound selected from among the group including AgInS, AgInS₂, CulnS, CuInS₂, AgGaS₂, CuGaS₂, CuGaO₂, AgGaO₂, AgAIO₂, and/or mixtures thereof, or a quaternary compound such as AgInGaS₂, and CuInGaS₂.

The III-V group compound may be selected from among the group including a binary compound selected from among the group including GaN, GaP, GaAs, GaSb, AlN, AlP, AlAs, AlSb, InN, InP, InAs, InSb, and/or mixtures thereof, a ternary compound selected from among the group including GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or mixtures thereof, and a quaternary compound selected from among the group including GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and/or mixtures thereof. The III-V group compound may further include a II group metal. For example, InZnP, and/or the like may be selected as a III-II-V group compound.

The IV-VI group compound may be selected from among the group including a binary compound selected from among the group including SnS, SnSe, SnTe, PbS, PbSe, PbTe, and/or mixtures thereof, a ternary compound selected from among the group including SnSeS, SnSeTe, SnSTe, PbSeS, PbSeTe, PbSTe, SnPbS, SnPbSe, SnPbTe, and/or mixtures thereof, and a quaternary compound selected from among the group including SnPbSSe, SnPbSeTe, SnPbSTe, and/or mixtures thereof.

Examples of the II-IV-V group semiconductor compound may be a ternary compound selected from among the group including ZnSnP, ZnSnP₂, ZnSnAs₂, ZnGeP₂, ZnGeAs₂, CdSnP₂, CdGeP₂, and/or mixtures thereof.

The IV group element may be selected from among the group including Si, Ge, and/or a mixture thereof. The IV group compound may be a binary compound selected from among the group including SiC, SiGe, and/or a mixture thereof.

Each element included in the multi-element compound such as the binary compound, ternary compound, and quaternary compound may exist in the particle at a uniform concentration or a non-uniform concentration. For example, the chemical formula indicates the type of element included in the compound, and the element ratio in the compound may be different. For example, AgInGaS₂ may indicate AgInₓGa₁₋ₓS₂ (x is a real number between 0 and 1).

In embodiments, the binary compound, the ternary compound or the quaternary compound may be present at uniform concentration in a particle or may be present at a partially different concentration distribution state in the same particle. In addition, a core/shell structure in which one quantum dot wraps another quantum dot may be possible. The core/shell structure may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, and/or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but one or more embodiment of the present disclosure may not be limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the present disclosure may not be limited thereto.

The quantum dot may have a full width of half maximum (FWHM) of emission wavelength spectrum of about 45 nm or less, suitably, about 40 nm or less, more suitably, about 30 nm or less. Within this range, color purity or color reproducibility may be improved. In addition, light emitted via such quantum dot is emitted in all directions, and light view angle properties may be improved.

In addition, the shape of the quantum dot may be generally utilized shapes in the art, without limitation. More suitably, the shape of spherical, pyramidal, multi-arm, or cubic nanoparticle, nanotube, nanowire, nanofiber, nanoplate particle, and/or the like may be utilized.

Because the energy band gap of the quantum dots may be controlled by controlling the size of the quantum dots or the element ratio in the quantum dot compound, light of suitable wavelengths may be obtained from the quantum dot emission layer. Therefore, by utilizing the quantum dots as described above (utilizing quantum dots of different sizes or having different element ratios in the quantum dot compound), a light-emitting device that may be to emit light of suitable wavelengths may be achieved. For example, the size of the quantum dots or the element ratio in the quantum dot compound may be selected, so that red, green, and/or blue light is emitted. In addition, the quantum dots may be configured to emit white light by combining light of suitable colors.

Referring again to FIG. 12, the light control layer CCL may include a first light control part CCP1 including a first quantum dot QD1 that converts a first color light provided from a light-emitting device ED into a second color light, a second light control part CCP2 including a second quantum dot QD2 that converts the first color light into a third color light, and a third light control part CCP3 that transmits the first color light. In one or more embodiments, the first light control part CCP1 may provide red light which is the second color light, and the second light control part CCP2 may provide green light which is the third color light. The third light control part CCP3 may transmit and provide blue light which is the first color light provided from the light-emitting device ED. For example, the first quantum dot QD1 may be a red quantum dot and the second quantum dot QD2 may be a green quantum dot. The same content as described above may be applied to the quantum dots QD1 and QD2.

In addition, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but include the scatterer SP.

The scatterer SP may be an inorganic particle. For example, the scatterer SP may include at least one among TiO₂, ZnO, Al₂O₃, SiO₂, and hollow silica. The scatterer SP may include at least one among TiO₂, ZnO, Al₂O₃, SiO₂, and hollow silica or may be a mixture of two or more materials selected from among TiO₂, ZnO, Al₂O₃, SiO₂, and/or hollow silica.

Each of the first light control part CCP1, the second light control part CCP2, and the third light control part CCP3 may include base resins BR1, BR2 and BR3, respectively, dispersing the quantum dots QD1 and QD2 and the scatterer SP. In one or more embodiments, the first light control part CCP1 may include the first quantum dot QD1 and the scatterer SP dispersed in the first base resin BR1, the second light control part CCP2 may include the second quantum dot QD2 and the scatterer SP dispersed in the second base resin BR2, and the third light control part CCP3 may include the scatterer particle SP dispersed in the third base resin BR3.

The base resins BR1, BR2 and BR3 are mediums in which the quantum dots QD1 and QD2 and the scatterer SP are dispersed and may be composed of suitable resin compositions which may be generally referred to as a binder. For example, the base resins BR1, BR2 and BR3 may be acrylic resins, urethane-based resins, silicone-based resins, epoxy-based resins, and/or the like. The base resins BR1, BR2 and BR3 may be transparent resins. In one or more embodiments, the first base resin BR1, the second base resin BR2 and the third base resin BR3 may be the same or different from each other.

The light control layer CCL may include a barrier layer BFL1. The barrier layer BFL1 may play the role of blocking the penetration of moisture and/or oxygen (hereinafter, will be referred to as “humidity/oxygen”). The barrier layer BFL1 may block the exposure of the light control parts CCP1, CCP2 and CCP3 to humidity/oxygen. The barrier layer BFL1 may cover the light control parts CCP1, CCP2 and CCP3. In addition, a color filter layer CFL, which will be explained later, may include a barrier layer BFL2 disposed on the light control parts CCP1, CCP2 and CCP3.

The barrier layers BFL1 and BFL2 may include at least one inorganic layer. For example, the barrier layers BFL1 and BFL2 may be provided (e.g., formed) by including an inorganic material. For example, the barrier layers BFL1 and BFL2 may be provided by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. The barrier layers BFL1 and BFL2 may further include an organic layer. The barrier layers BFL1 and BFL2 may be composed of a single layer or a plurality of layers.

In the display device DD-a, the color filter layer CFL may be disposed on the light control layer CCL. For example, the color filter layer CFL may be disposed directly on the light control layer CCL. In embodiments, the barrier layer BFL2 may not be repeated.

The color filter layer CFL may include filters CF1, CF2 and CF3. Each of the first to third filters CF1, CF2 and CF3 may be disposed corresponding to a red light-emitting area PXA-R, a green light-emitting area PXA-G, and a blue light-emitting area PXA-B, respectively.

The color filter layer CFL may include a first filter CF1 transmitting the second color light, a second filter CF2 transmitting the third color light, and a third filter CF3 transmitting the first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye.

One or more embodiment of the present disclosure may not be limited thereto, and the third filter CF3 may not include the pigment or dye. The third filter CF3 may include a polymer photosensitive resin and not include a pigment or dye. The third filter CF3 may be transparent. The third filter CF3 may be provided utilizing a transparent photosensitive resin.

In addition, in one or more embodiments, the first filter CF1 and the second filter CF2 may be yellow filters. The first filter CF1 and the second filter CF2 may be provided as one body without distinction.

In embodiments, the color filter layer CFL may further include a light-shielding part. The light-shielding part may be a black matrix. The light-shielding part may be provided by including an organic light-shielding material or an inorganic light-shielding material including a black pigment or black dye. The light-shielding part may prevent or reduce light leakage phenomenon and divide the boundaries among adjacent filters CF1, CF2 and CF3.

On the color filter layer CFL, a base substrate BL may be disposed. The base substrate BL may be a substrate providing a base surface on which the color filter layer CFL, the light control layer CCL, and/or the like may be disposed. The base substrate BL may be a glass substrate, a metal substrate, a plastic substrate, and/or the like. However, one or more embodiments of the present disclosure may not be limited thereto, and the base substrate BL may be an inorganic layer, an organic layer or a composite material layer. In addition, the base substrate BL may not be repeated here.

Hereinafter, a method for manufacturing a light-emitting device according to one or more embodiments of the present disclosure will be described with reference to the drawings.

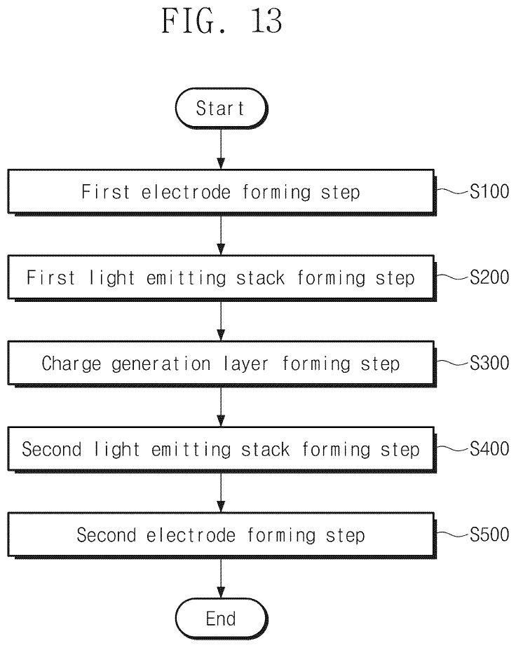

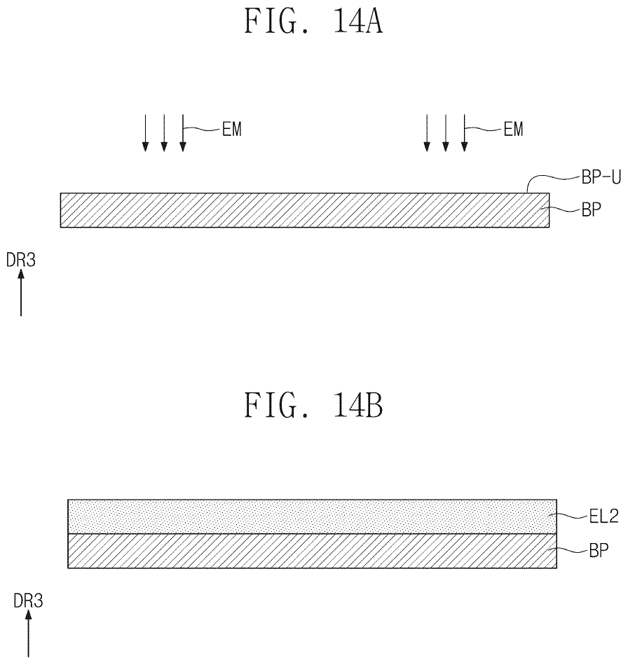

FIG. 13 is a flowchart showing a method for manufacturing a light-emitting device according to one or more embodiments of the present disclosure. FIGS. 14A and 14B are cross-sectional views showing some operations of a method for manufacturing a light-emitting device according to one or more embodiments of the present disclosure. FIGS. 14A and 14B show the operations of forming a second electrode in the method for manufacturing a light-emitting device.

Hereinafter, if (e.g., when) describing a method for manufacturing a light-emitting device according to one or more embodiments with reference to FIGS. 13, 14A and 14B, the same reference symbols are given to the same components as those described above, and detailed descriptions may not be repeated.

The method for manufacturing a light-emitting device according to one or more embodiments may include an operation of forming a first electrode, an operation of forming a plurality of light-emitting stacks on the first electrode, an operation of forming a charge generation layer disposed between the plurality of light-emitting stacks, and an operation of forming a second electrode. According to the method for manufacturing a light-emitting device according to one or more embodiments, light-emitting devices ED-a and ED-b in which a first electrode EL1, a functional layer FL, a second electrode EL2, and a capping layer CPL are sequentially stacked as illustrated in FIG. 9 or FIG. 10 may be manufactured. The functional layer FL may include a plurality of light-emitting stacks EU-1, EU-2 and EU-3 (see FIGS. 9 and 10), and charge generation layers CGL-1 and CGL-2 disposed between the plurality of light-emitting stacks EU-1, EU-2 and EU-3 (see FIGS. 9 and 10).

Referring to FIG. 13, the method for manufacturing a light-emitting device according to one or more embodiments may include an operation of forming a first electrode (S100), an operation of forming a first light-emitting stack (S200), an operation of forming a charge generation layer (S300), an operation of forming a second light-emitting stack (S400), and an operation of forming a second electrode (S500). The method for manufacturing a light-emitting device may further include an operation of forming one or more light-emitting stacks on the second light-emitting stack prior to the operation of forming the second electrode.

Referring to FIG. 14A, an operation of preparing a preliminary light-emitting device BP may be performed prior to the operation of forming the second electrode. The preliminary light-emitting device BP may refer to a light-emitting device before the second electrode EL2 and the capping layer CPL may be provided in the light-emitting devices ED-a and ED-b illustrated in FIG. 9 or FIG. 10. The preliminary light-emitting device BP may include a top surface BP-U which is a reference surface on which the second electrode EL2 may be provided. The top surface BP-U of the preliminary light-emitting device BP may be defined by the top surface of an electron transport region included in the uppermost light-emitting stack. For example, if (e.g., when) the light-emitting device ED may have a structure illustrated in FIG. 9, the second electron transport region ETR-2 may define the top surface BP-U of the preliminary light-emitting device BP. In embodiments, if (e.g., when) the light-emitting device ED may have the structure illustrated in FIG. 10, the third electron transport region ETR-3 may define the top surface BP-U of the preliminary light-emitting device BP.

According to the operation of forming the second electrode according to one or more embodiments, a second electrode EL2 including a silver (Ag)-palladium (Pd)-copper (Cu) alloy may be provided as illustrated in FIGS. 14A and 14B. The operation of forming the second electrode EL2 may be an operation of forming the second electrode EL2 on the preliminary light-emitting device BP. The second electrode EL2 may be provided on the top surface BP-U of the preliminary light-emitting device BP.

In one or more embodiments, the second electrode EL2 may be provided directly on the uppermost light-emitting stack among the plurality of light-emitting stacks. For example, if (e.g., when) the light-emitting device ED may have the structure illustrated in FIG. 9, the second electrode EL2 may be provided directly on the second light-emitting stack EU-2. For example, the second electrode EL2 may be provided directly on the second electron transport region ETR-2. In embodiments, if (e.g., when) the light-emitting device ED may have the structure illustrated in FIG. 10, the second electrode EL2 may be provided directly on the third light-emitting stack EU-3. For example, the second electrode EL2 may be provided directly on the third electron transport region ETR-3.

The second electrode EL2 may be provided by providing a deposition material EM. The deposition material EM may be provided through a sputtering process. The deposition material EM may include silver (Ag), palladium (Pd), and copper (Cu). In one or more embodiments, the deposition material EM is composed of silver (Ag), palladium (Pd) and copper (Cu), and may not include other materials. However, one or more embodiments of the present disclosure may not be limited thereto, and the deposition material EM may further include nickel (Ni) in addition to silver (Ag), palladium (Pd) and copper (Cu). In embodiments, the deposition material EM is composed of silver (Ag), palladium (Pd), copper (Cu) and nickel (Ni), and may not include other materials.

Hereinafter, a light-emitting device according to one or more embodiments of the present disclosure will be described with reference to an example and a comparative example. In addition, the example shown below is an illustration to help understanding of the present disclosure, and the scope of the present disclosure is not limited thereto.

### Example

### 1. Manufacturing of Displays of Example and Comparative Example Manufacturing of Display of Example

A display applying a light-emitting device having a stacked structure of FIG. 9 was manufactured. The display of the Example may include a display panel and an input sensor described in FIG. 5. The light-emitting device included in the display panel of the Example was manufactured by the method below.

The light-emitting device of the Example was manufactured as a tandem light-emitting device by forming a first electrode on a glass substrate, sequentially forming a first light-emitting stack, a charge generation layer, and a second light-emitting stack on the first electrode and then forming a second electrode and a capping layer. The tandem light-emitting device of the Example was manufactured based on the light-emitting device structure illustrated in FIG. 9.

Between the stacked light-emitting structures, a charge generation layer including an n-type charge generation layer and a p-type charge generation layer was provided. An n-type charge generation layer was provided by doping Li into 2,9-dimethyl-4,7-diphenyl-1,10-phenanthroline (BCP). In the n-type charge generation layer, BCP and Li were provided in a weight ratio of about 90:10. The n-type charge generation layer was provided to a thickness of about 65 Å.

On the n-type charge generation layer, a p-type charge generation layer was provided utilizing 1,4,5,8,9,11-hexaazatriphenylenehexacarbonitrile (HATCN). The p-type charge generation layer was provided to a thickness of about 50 Å.

The first electrode was provided to have a structure of ITO/Ag/ITO. In the first and second light-emitting stacks EU-1 and EU-2 (shown in FIG. 9), the hole transport region was fabricated by providing (e.g., forming) N,N′-di(1-naphthyl)-N,N′-diphenyl-(1,1′-biphenyl)-4,4′-diamine (NPB) with a thickness of about 250 Å and forming 4,4′,4″-tris(N-carbazolyl)triphenylamine (TCTA) with a thickness of about 75 Å on the NPB layer.

In the first and second light-emitting stacks EU-1 and EU-2 (shown in FIG. 9), an electron transport region was provided by including a 2,4,6-tris(biphenyl-3-yl)-1,3,5-triazine (T2T) layer with a thickness of about 50 Å, and a layer obtained by adding Liq to 2,4,6-tris(3-(pyrimidin-5-yl)phenyl)-1,3,5-triazine (TPM-TAZ) and co-depositing to a thickness of about 100 Å. In the electron transport region, TPM-TAZ and Liq were included in a weight ratio of about 5:5.

Each layer of the light-emitting structures was provided by a deposition method under vacuum conditions.

Ag, Pd, and Cu were provided on the second light-emitting stack by a sputtering method, and a second electrode made of a silver (Ag)-palladium (Pd)-copper (Cu) alloy with a weight ratio of about 98.96:0.06:0.98 was provided to a thickness of about 113 Å. On the second electrode, a capping layer with a thickness of about 500 Å was provided utilizing P4.

### Manufacturing of Display of Comparative Example

A display was manufactured in the same manner as in the Example except that the second electrode was made of a silver (Ag)-magnesium (Mg) alloy provided in a weight ratio (wt %) of about 98.2:1.8 utilizing silver (Ag) and magnesium (Mg).

### 2. Evaluation of the Displays

For the displays of the Example and Comparative Example provided through the above-mentioned manufacturing examples, the sheet resistance, voltage drop (IR drop), power consumption improvement rate, and touch noise improvement rate of the second electrode were compared and shown in Table 2 below. The sheet resistance was measured utilizing a 4-terminal measurement (4 point probe) method. In addition, the power consumption improvement rate of the Example in Table 2 is expressed as the power consumption improvement rate measured at the same white 600 nit. It shows the reduced rate based on the power consumption of the Comparative Example in which the white efficiency was measured according to the change in the sheet resistance of the second electrode. In embodiments of the touch noise, the input sensor located above the display panel affects the touch driving signals by the electrical signals generated if (e.g., when) the lower display panel is driven. For measurement, the amount of noise compared to the actual signal is measured if (e.g., when) performing a touch utilizing a touch bar while driving the display panel.

TABLE 2

| | Example | Comparative Example |
|---|---|---|
| Sheet resistance | 5.9 Ω/□ | 12 Ω/□ |
| IR drop (V) | 0.83 | 1.24 |
| Power consumption | 2.2% | — |
| improvement rate (%) | | |
| Touch noise improvement rate | 23~28 | — |
| (%) | | |

Referring to Table 2, in terms of the Example, the sheet resistance was about 5.9Ω/□, which was significantly reduced compared to the sheet resistance of the light-emitting device of the Comparative Example, which was about 12Ω/□. In addition, the IR drop of the light-emitting device of the Example was about 0.83 V, which was significantly reduced compared to the IR drop of the Comparative Example, which was about 1.24 V. In terms of power consumption, it was confirmed that the power consumption of the Example was improved by about 2.2% compared to the power consumption of the Comparative Example. In addition, in terms of touch noise, it was confirmed that the touch noise of the Example was reduced by about 23-28% compared to the Comparative Example. It was confirmed in Table 2 that if (e.g., when) the sheet resistance of the second electrode is low, the signal of the display panel is shielded by the second electrode, so that the signal noise of the display panel does not affect the input sensor area, thereby reducing the noise improvement rate. In the embodiment of the Example, it was confirmed that the touch noise was reduced by about 23-28% if (e.g., when) the sheet resistance was reduced to about 5.9 Ω/□.

In one or more embodiments, the light-emitting device present disclosure may form a second electrode, which may be a common electrode, with a silver (Ag) palladium (Pd)-copper (Cu) alloy, and by controlling silver (Ag), palladium (Pd), and/or copper (Cu) in the alloy to corresponding content ranges, the sheet resistance of the second electrode may be effectively reduced without significantly increasing the thickness. Accordingly, the voltage drop phenomenon occurring in the common electrode may be reduced while stably maintaining suitable optical characteristics, and the power consumption may be reduced by reducing the driving voltage.

According to one or more embodiments of the present disclosure, the sheet resistance of a common electrode in a tandem light-emitting device including a plurality of light-emitting stacks may be reduced, so that the emission efficiency of the light-emitting device may be improved.

According to one or more embodiments of the present disclosure, the emission efficiency of an electronic device including a tandem light-emitting device with reduced voltage drop may be improved, and power consumption may be improved.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display apparatus, a device of manufacturing a display apparatus, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although the present disclosure has been described above with reference to suitable embodiments thereof, it will be understood that those skilled in the art or having ordinary knowledge in the art may modify and change the present disclosure in suitable ways without departing from the spirit and technical scope of the present disclosure and equivalents thereof as described in the claims below.

Therefore, the technical scope of the present disclosure should not be limited to the contents described in the detailed description of the specification, but should be determined by the claims.

1. A light-emitting device comprising:
a first electrode;
a second electrode above the first electrode and comprising a silver (Ag)-palladium (Pd)-copper (Cu) alloy;
light-emitting stacks between the first electrode and the second electrode, respective light-emitting stacks comprising an emission layer; and
a charge generation layer between the light-emitting stacks,
wherein the second electrode comprises, based on 100 wt % of a total weight of the Ag—Pd—Cu alloy:
greater than about 97.9 wt % and about 99.9 wt % or less of Ag;
about 0.01 wt % or more and less than about 0.1 wt % of Pd; and
about 0.01 wt % or more and about 2.0 wt % or less of Cu.

2. The light-emitting device of claim 1, wherein the Ag—Pd—Cu alloy further comprises nickel (Ni).

3. The light-emitting device of claim 2, wherein the Ag—Pd—Cu alloy further comprises, based on 100 wt % of the total weight of the Ag—Pd—Cu alloy, about 0.01 wt % or more and about 2.0 wt % or less of Ni.

4. The light-emitting device of claim 1, wherein the second electrode consists of the Ag—Pd—Cu alloy.

5. The light-emitting device of claim 4, wherein a content of Pd in the second electrode is less than a content of Cu in the second electrode.

6. The light-emitting device of claim 1,
wherein the light-emitting stacks comprise:
a first light-emitting stack comprising a first emission layer; and
a second light-emitting stack comprising a second emission layer, and
wherein the charge generation layer is between the first light-emitting stack and the second light-emitting stack.

7. The light-emitting device of claim 6,
wherein the first light-emitting stack comprises:
a first hole transport region between the first electrode and the first emission layer; and
a first electron transport region between the first emission layer and the charge generation layer, and
wherein the second light-emitting stack comprises:
a second hole transport region between the charge generation layer and the second emission layer; and
a second electron transport region between the second emission layer and the second electrode.

8. The light-emitting device of claim 7, wherein the second electrode is directly above the second electron transport region.

9. The light-emitting device of claim 1,
wherein the light-emitting device further comprises a capping layer above the second electrode, and
wherein a refractive index of the capping layer is about 1.6 or more for light in a wavelength range of about 550 nm or more and about 660 nm or less.

10. The light-emitting device of claim 1, wherein the second electrode is a cathode.

11. The light-emitting device of claim 1, wherein the first electrode comprises at least one metal selected from among Ag, Magnesium (Mg), Cu, Aluminum (AI), Platinum (Pt), Pd, Gold (Au), Nickel (Ni), Neodymium (Nd), Iridium (Ir), Chromium (Cr), Lithium (Li), Calcium (Ca), Lithium Fluoride (LiF), Molybdenum (Mo), Titanium (Ti), Tungsten (W), Indium (In), Tin (Sn), and Zinc (Zn), a compound of two or more metals selected from among Ag, Mg, Cu, Al, Pt, Pd, Au, Ni, Nd, Ir, Cr, Li, Ca, LiF, Mo, Ti, W, In, Sn, and Zn, or at least one selected from among indium tin oxide (ITO), indium zinc oxide (IZO), zinc oxide (ZnO), and indium tin zinc oxide (ITZO).

12. The light-emitting device of claim 1, wherein a thickness of the second electrode is about 30 Å or more and about 120 Å or less.

13. The light-emitting device of claim 1, wherein a sheet resistance of the second electrode is about 10Ω/□ or less.

14. An electronic device comprising:
a display comprising a display panel and providing an image; and
a power supply supplying power to the display,
wherein the display panel comprises:
a base layer comprising light-emitting areas and a non-light-emitting area adjacent to the light-emitting areas;
a circuit layer above the base layer; and
a display device layer above the circuit layer and comprising light-emitting devices corresponding to the light-emitting areas, respectively,
at least some of the light-emitting devices comprise:
a first electrode;
a second electrode above the first electrode and comprising a silver (Ag)-palladium (Pd)-copper (Cu) alloy;
light-emitting stacks between the first electrode and the second electrode, respective light-emitting stacks comprising an emission layer; and
a charge generation layer between the light-emitting stacks, and
wherein the second electrode comprises, based on 100 wt % of a total weight of the Ag—Pd—Cu alloy:
greater than about 97.9 wt % or and about 99.9 wt % or less of Ag;
about 0.01 wt % or more and less than about 0.1 wt % of Pd; and
about 0.01 wt % or more and about 2.0 wt % or less of Cu.

15. The electronic device of claim 14, further comprising at least one selected from among a processor and a memory.

16. The electronic device of claim 14, wherein the electronic device is a television, a monitor, an outdoor billboard, a personal computer, a notebook computer, a personal digital assistant, a vehicle device, a game console, a smartphone, a tablet, a smartwatch, or a camera.

17. The electronic device of claim 14,
wherein the light-emitting devices comprise a first light-emitting device, a second light-emitting device, and a third light-emitting device, spaced apart in a direction perpendicular to a thickness direction, and
the first light-emitting device is to emit light of a first wavelength, the second light-emitting device is to emit light of a second wavelength longer than the first wavelength, and the third light-emitting device is to emit light of a third wavelength longer than the second wavelength.

18. A method comprising:
forming a first electrode;
forming a first light-emitting stack comprising a first emission layer above the first electrode;
forming a first charge generation layer above the first light-emitting stack;
forming a second light-emitting stack above the first charge generation layer; and
forming a second electrode comprising a silver (Ag)-palladium (Pd)-copper (Cu) alloy above the second light-emitting stack,
wherein the second electrode comprises, based on 100 wt % of a total weight of the Ag—Pd—Cu alloy:
greater than about 97.9 wt % and about 99.9 wt % or less of Ag;
about 0.01 wt % or more and less than about 0.1 wt % of Pd; and
about 0.01 wt % or more and about 2.0 wt % or less of Cu, and
wherein the method is a method for manufacturing a light-emitting device.

19. The method of claim 18, wherein the forming of the second electrode comprises a sputtering process.

20. The method of claim 18, wherein the second electrode is provided directly above the second light-emitting stack.
